(19) United States
(12) Patent Application Publication
(10) Pub. No.: US 2025/0048696 A1
(43) Pub. Date: Feb. 6, 2025

(54) SEMICONDUCTOR DEVICE AND METHOD OF FABRICATING THE SAME

(71) Applicant: SAMSUNG ELECTRONICS CO., LTD., Suwon-si (KR)

(72) Inventors: KI HWAN KIM, Sueon-si (KR); Unki Kim, Suwon-si (KR); Chanyoung Kim, Suwon-si (KR); Jeongho Yoo, Suwon-si (KR); Ingyu Jang, Suwon-si (KR); Sujin Jung, Suwon-si (KR)

(73) Assignee: SAMSUNG ELECTRONICS CO., LTD., Suwon-si (KR)

(21) Appl. No.: 18/609,885

(22) Filed: Mar. 19, 2024

(30) Foreign Application Priority Data
Aug. 4, 2023 (KR) 10-2023-0102148

(51) Int. Cl. H01L 29/08; H01L 29/06; H01L 29/423; H01L 29/66; H01L 29/775

(52) U.S. Cl. CPC H01L 29/0847; H01L 29/0673; H01L 29/42392; H01L 29/66439; H01L 29/66545; H01L 29/775

(57) ABSTRACT

A semiconductor device includes a substrate including an active pattern, a channel pattern on the active pattern, the channel pattern including a first semiconductor pattern, a second semiconductor pattern, and a third semiconductor pattern sequentially stacked and vertically spaced apart, a source/drain pattern on the active pattern, and a gate electrode on the first semiconductor pattern, the second semiconductor pattern, and the third semiconductor pattern, where the source/drain pattern includes a buffer layer and a main layer on the buffer layer, the main layer includes silicon that is doped with an impurity, an impurity concentration of the main layer is a first atomic fraction at a first level corresponding to the first semiconductor pattern, and the impurity concentration of the main layer is a second atomic fraction at a second level corresponding to the second semiconductor pattern.

### CROSS-REFERENCE TO RELATED APPLICATIONS

This application is based on and claims priority under 35 U.S.C. § 119 to Korean Patent Application No. 10-2023-0102148, filed on Aug. 4, 2023, in the Korean Intellectual Property Office, the disclosure of which is incorporated herein by reference in its entirety.

### BACKGROUND

Example embodiments of the disclosure relate to a semiconductor device and a method of fabricating the same, and in particular, to a semiconductor device including a field effect transistor (FET) and a method of fabricating the same.

A semiconductor device may include an integrated circuit composed of metal-oxide-semiconductor FETs (MOSFETs). To meet an increasing demand for a semiconductor device with a small pattern size and a reduced design rule, the MOSFETs are being scaled down. The down-scaling of the MOSFETs may lead to deterioration in operational properties of the semiconductor device.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device with improved electrical and reliability characteristics, and a method of fabricating a semiconductor device thereof.

Additional aspects will be set forth in part in the description which follows and, in part, will be apparent from the description, or may be learned by practice of the presented embodiments.

According to an aspect of an example embodiment, a semiconductor device may include a substrate including an active pattern, a channel pattern on the active pattern, the channel pattern including a first semiconductor pattern, a second semiconductor pattern, and a third semiconductor pattern sequentially stacked and vertically spaced apart, a source/drain pattern on the active pattern, and a gate electrode on the first semiconductor pattern, the second semiconductor pattern, and the third semiconductor pattern, where the source/drain pattern includes a buffer layer and a main layer on the buffer layer, the main layer includes silicon that is doped with an impurity, an impurity concentration of the main layer is a first atomic fraction at a first level corresponding to the first semiconductor pattern, the impurity concentration of the main layer is a second atomic fraction at a second level corresponding to the second semiconductor pattern, the impurity concentration of the main layer is a third atomic fraction at a third level corresponding to the third semiconductor pattern, and the first atomic fraction is greater than the third atomic fraction.

According to an aspect of an example embodiment, a semiconductor device may include a substrate including an active pattern, a channel pattern on the active pattern, the channel pattern including a plurality of semiconductor patterns stacked and vertically spaced apart, a source/drain pattern on the active pattern, and a gate electrode on the plurality of semiconductor patterns, where the source/drain pattern includes an impurity, the impurity includes at least one of phosphorus, arsenic, and antimony, an uppermost semiconductor pattern of the plurality of semiconductor patterns is located at a first level, a lowermost semiconductor pattern of the plurality of semiconductor patterns is located at a second level, and an impurity concentration of the source/drain pattern increases from the first level to the second level.

According to an aspect of an example embodiment, a semiconductor device may include a substrate including an n-type metal-oxide-semiconductor (MOS) field effect transistor (FET) (NMOSFET) region, an active pattern on the NMOSFET region, a channel pattern on the active pattern, the channel pattern including a plurality of semiconductor patterns stacked and spaced apart, the plurality of semiconductor patterns including a first semiconductor pattern, a second semiconductor pattern adjacent to the first semiconductor pattern, and an uppermost semiconductor pattern, a source/drain pattern on the active pattern and including an impurity, a gate electrode on the channel pattern, the gate electrode including an inner electrode between the first semiconductor pattern and the second semiconductor pattern, and an outer electrode on the uppermost semiconductor pattern, a gate insulating layer between the inner electrode and the source/drain pattern, a gate spacer on a side surface of the outer electrode, a gate capping pattern on a top surface of the outer electrode, an interlayer insulating layer on the gate capping pattern and the source/drain pattern, a gate contact connected to the gate electrode and penetrating the interlayer insulating layer and the gate capping pattern, an active contact connected to the source/drain pattern and penetrating the interlayer insulating layer and a first metal layer on the interlayer insulating layer, where the first metal layer includes first interconnection lines respectively connected to the gate contact and the active contact, a length of the first semiconductor pattern is greater than a length of the second semiconductor pattern, an impurity concentration of the source/drain pattern is a first atomic fraction at a first level corresponding to the first semiconductor pattern, the impurity concentration of the source/drain pattern is a second atomic fraction at a second level corresponding to the second semiconductor pattern, and the first atomic fraction is greater than the second atomic fraction.

### BRIEF DESCRIPTION OF DRAWINGS

The above and other aspects, features, and advantages of certain example embodiments of the present disclosure will be more apparent from the following description taken in conjunction with the accompanying drawings, in which:

FIGS. 1 to 3 are diagrams illustrating logic cells of a semiconductor device according to one or more example embodiments of the disclosure;

FIG. 4 is a plan view illustrating a semiconductor device according to one or more example embodiments of the disclosure;

FIGS. 5A to 5D are cross-sectional views taken along lines A-A′, B-B′, C-C′, and D-D′ of FIG. 4, respectively, according to one or more example embodiments of the disclosure;

FIG. 6A is an enlarged cross-sectional view illustrating a portion ‘M’ of FIG. 5B according to one or more example embodiments of the disclosure;

FIG. 6B is an enlarged cross-sectional view illustrating the portion ‘M’ of FIG. 5B according to one or more example embodiments of the disclosure;

FIGS. 7A to 12C are cross-sectional views illustrating a method of fabricating a semiconductor device, according to one or more example embodiments of the disclosure; and

FIGS. 13, 14, and 15 are enlarged cross-sectional views illustrating a portion “M” of FIG. 10B and illustrating a method of forming a second source/drain pattern according to one or more example embodiments of the disclosure.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

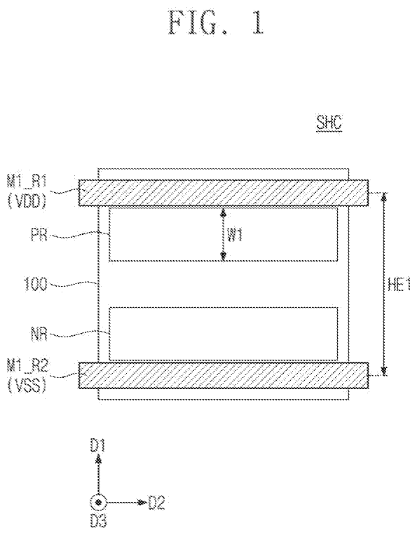

FIGS. 1 to 3 are diagrams illustrating logic cells of a semiconductor device according to one or more example embodiments of the disclosure.

Referring to FIG. 1, a single height cell SHC may be provided. A first power line M1_R1 and a second power line M1_R2 may be provided on a substrate 100. The first power line M1_R1 may be a conduction path, to which a drain voltage VDD (e.g., a power voltage) is provided. The second power line M1_R2 may be a conduction path, to which a source voltage VSS (e.g., a ground voltage) is provided.

The single height cell SHC may be defined between the first power line M1_R1 and the second power line M1_R2. The single height cell SHC may include one p-type metal-oxide-semiconductor (MOS) field effect transistor (FET) (MOSFET) (PMOSFET) region PR and one n-type MOSFET (NMOSFET) region NR. For example, the single height cell SHC may have a complementary MOS (CMOS) structure provided between the first and second power lines M1_R1 and M1_R2.

Each of the PMOSFET and NMOSFET regions PR and NR may have a first width W1 in a first direction D1. A length of the single height cell SHC in the first direction D1 may be defined as a first height HE1. The first height HE1 may be substantially equal to a distance (e.g., a pitch) between the first and second power lines M1_R1 and M1_R2.

The single height cell SHC may constitute a single logic cell. The logic cell may refer to a logic device (e.g., AND, OR, XOR, XNOR, inverter, and so forth), which is configured to execute a logic function or operation. For example, the logic cell may include transistors constituting the logic device and interconnection lines connecting the transistors to each other or other circuit elements in the logic cell or outside the logic cell.

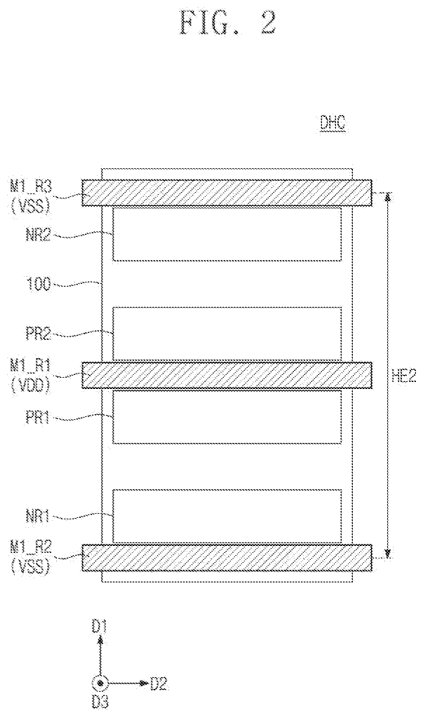

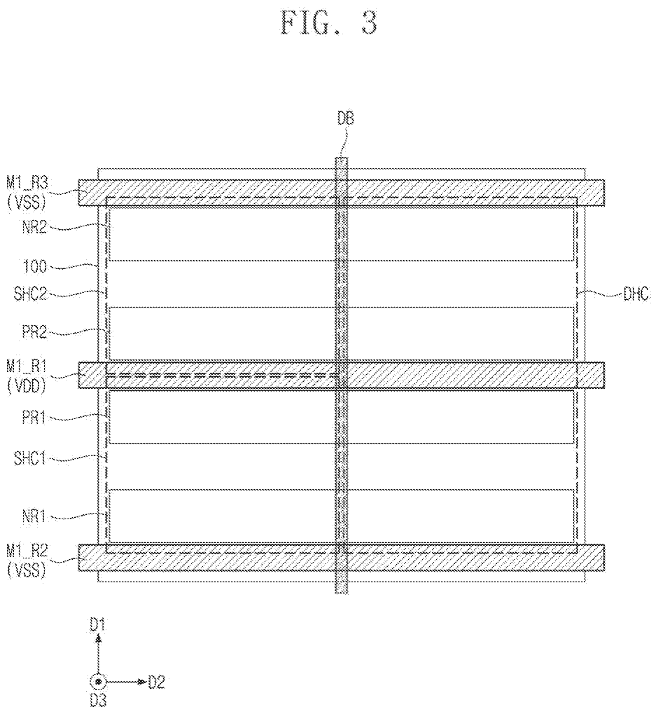

Referring to FIG. 2, a double height cell DHC may be provided. The first power line M1_R1, the second power line M1_R2, and a third power line M1_R3 may be provided on the substrate 100. The first power line M1_R1 may be disposed between the second power line M1_R2 and the third power line M1_R3. The third power line M1_R3 may be a conduction path, to which the drain voltage VDD is provided.

The double height cell DHC may be defined between the second power line M1_R2 and the third power line M1_R3. The double height cell DHC may include a first PMOSFET region PR1, a second PMOSFET region PR2, a first NMOSFET region NR1, and a second NMOSFET region NR2.

The first NMOSFET region NR1 may be adjacent to the second power line M1_R2. The second NMOSFET region NR2 may be adjacent to the third power line M1_R3. The first and second PMOSFET regions PR1 and PR2 may be adjacent to the first power line M1_R1. In a plan view, the first power line M1_R1 may be disposed between the first and second PMOSFET regions PR1 and PR2.

A length of the double height cell DHC in the first direction D1 may be defined as a second height HE2. The second height HE2 may be about two times the first height HE1 of FIG. 1. The first and second PMOSFET regions PR1 and PR2 of the double height cell DHC may be combined to operate as a single PMOSFET region.

Thus, a channel size of a PMOSFET of the double height cell DHC may be greater than a channel size of a PMOSFET of the single height cell SHC previously described with reference to FIG. 1. For example, the channel size of the PMOSFET of the double height cell DHC may be about two times the channel size of the PMOSFET of the single height cell SHC. In this case, the double height cell DHC may be operated at a higher speed than the single height cell SHC. In an embodiment, the double height cell DHC shown in FIG. 2 may be defined as a multi-height cell. The multi-height cell may include a triple height cell with a cell height about three times that of the single height cell SHC.

Referring to FIG. 3, a first single height cell SHC1, a second single height cell SHC2, and the double height cell DHC may be two-dimensionally disposed on the substrate 100. The first single height cell SHC1 may be disposed between the first and second power lines M1_R1 and M1_R2. The second single height cell SHC2 may be disposed between the first and third power lines M1_R1 and M1_R3. The second single height cell SHC2 may be adjacent to the first single height cell SHC1 in the first direction D1.

The double height cell DHC may be disposed between the second and third power lines M1_R2 and M1_R3. The double height cell DHC may be adjacent to the first and second single height cells SHC1 and SHC2 in a second direction D2.

A division structure DB may be provided between the first single height cell SHC1 and the double height cell DHC and between the second single height cell SHC2 and the double height cell DHC. The active region of the double height cell DHC may be electrically separated from the active region of each of the first and second single height cells SHC1 and SHC2 by the division structure DB.

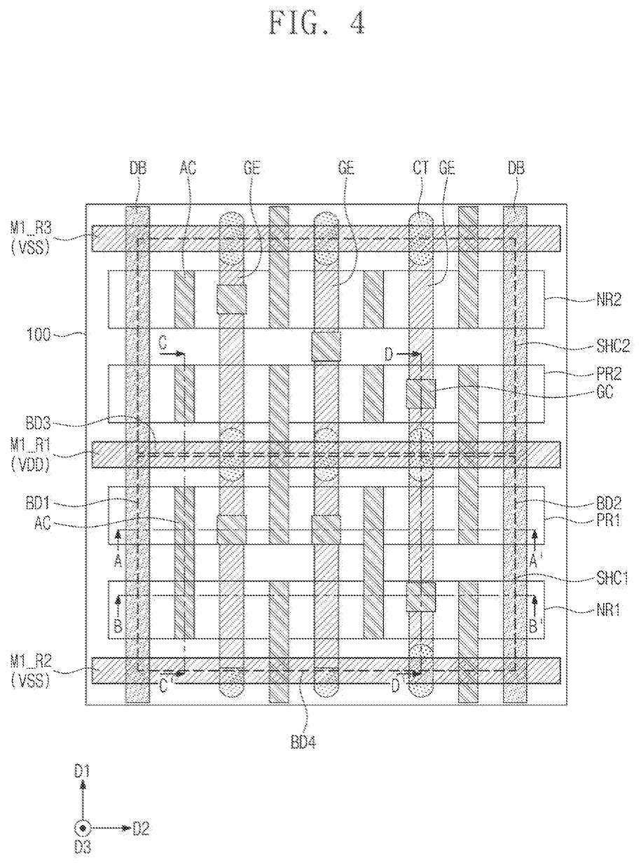

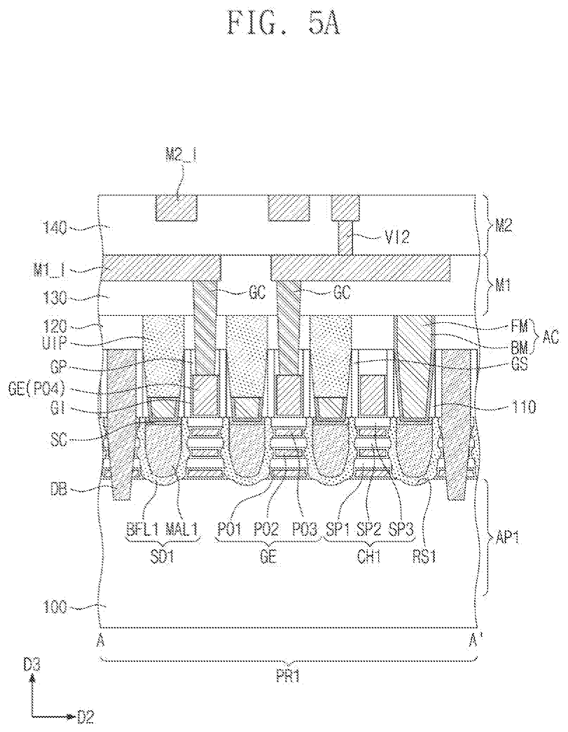

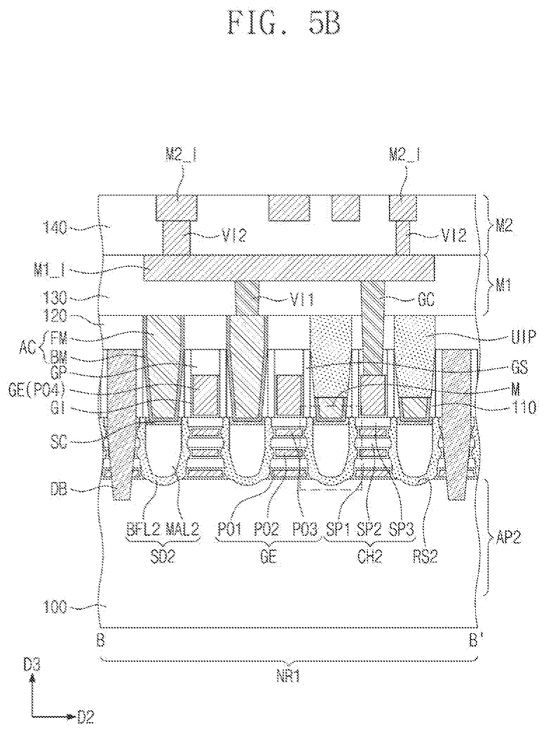

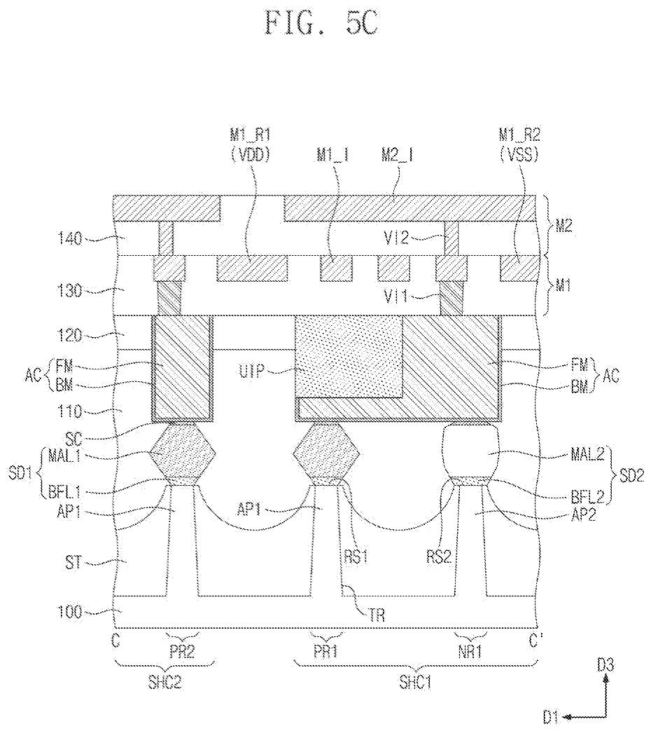

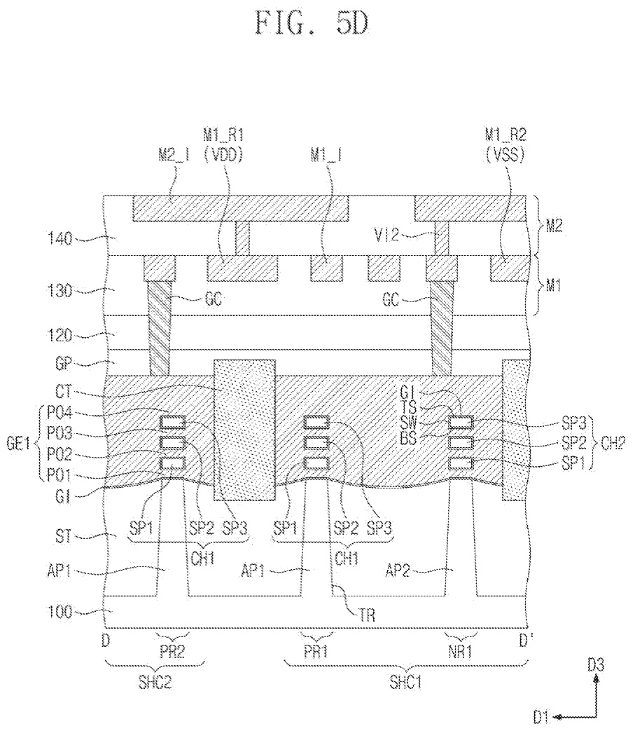

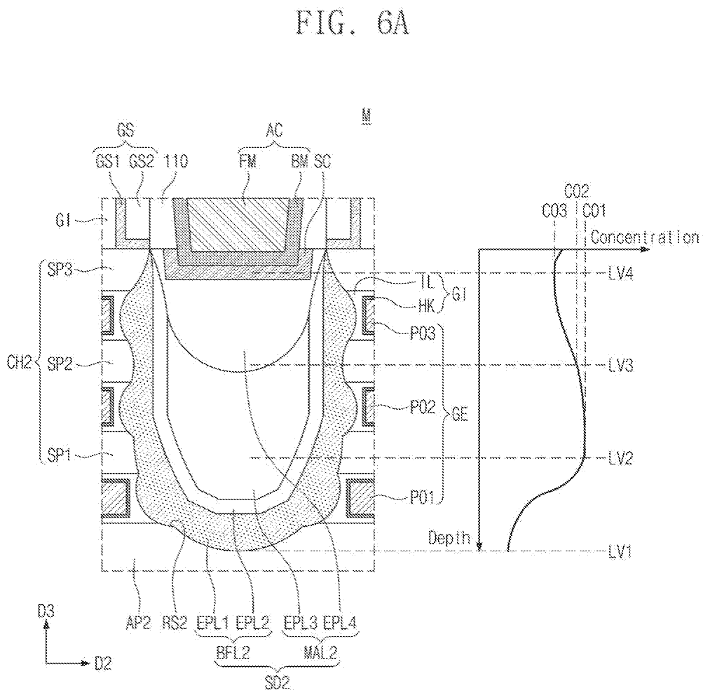

FIG. 4 is a plan view illustrating a semiconductor device according to one or more example embodiments of the disclosure. FIGS. 5A to 5D are cross-sectional views taken along lines A-A′, B-B′, C-C′, and D-D′ of FIG. 4, respectively, according to one or more example embodiments of the disclosure.

Referring to FIGS. 4 and 5A to 5D, the first and second single height cells SHC1 and SHC2 may be provided on the substrate 100. Logic transistors constituting the logic circuit may be disposed on each of the first and second single height cells SHC1 and SHC2. The substrate 100 may be a semiconductor substrate that is formed of or includes silicon, germanium, silicon germanium, a compound semiconductor material, or the like. In an embodiment, the substrate 100 may be a silicon wafer.

The substrate 100 may include the first PMOSFET region PR1, the second PMOSFET region PR2, the first NMOSFET region NR1, and the second NMOSFET region NR2. Each of the first PMOSFET region PR1, the second PMOSFET region PR2, the first NMOSFET region NR1, and the second NMOSFET region NR2 may extend in the second direction D2. The first single height cell SHC1 may include the first NMOSFET region NR1 and the first PMOSFET region PR1, and the second single height cell SHC2 may include the second PMOSFET region PR2 and the second NMOSFET region NR2.

A first active pattern AP1 and a second active pattern AP2 may be defined by a trench TR, which is formed in an upper portion of the substrate 100. The first active pattern AP1 may be provided on each of the first and second PMOSFET regions PR1 and PR2. The second active pattern AP2 may be provided on each of the first and second NMOSFET regions NR1 and NR2. The first and second active patterns AP1 and AP2 may extend in the second direction D2. Each of the first and second active patterns AP1 and AP2 may be a vertically-protruding portion of the substrate 100.

A device isolation layer ST may be provided to fill or at least partially fill the trench TR. The device isolation layer ST may include a silicon oxide layer. The device isolation layer ST may not cover first and second channel patterns CH1 and CH2 to be described below.

The first channel pattern CH1 may be provided on the first active pattern AP1. The second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3, which are sequentially stacked. The first to third semiconductor patterns SP1, SP2, and SP3 may be spaced apart from each other in a vertical direction (i.e., a third direction D3).

Each of the first to third semiconductor patterns SP1, SP2, and SP3 may be formed of or include at least one of silicon (Si), germanium (Ge), and silicon germanium (SiGe). In an embodiment, each of the first to third semiconductor patterns SP1, SP2, and SP3 may be formed of or include crystalline silicon. The first to third semiconductor patterns SP1, SP2, and SP3 may be nanosheets, which are stacked.

In an embodiment, each of the first and second channel patterns CH1 and CH2 may include three nano sheets. However, the disclosure is not limited thereto, and in an embodiment, each of the first and second channel patterns CH1 and CH2 may independently include two or more nano sheets.

The first to third semiconductor patterns SP1, SP2, and SP3 may have lengths that are different from each other in the second direction D2. In an embodiment, the length of the second semiconductor pattern SP2 may be greater than the length of the third semiconductor pattern SP3. The length of the first semiconductor pattern SP1 may be greater than the length of the second semiconductor pattern SP2. That is, the first semiconductor pattern SP1 may be the longest among the first to third semiconductor patterns SP1, SP2, and SP3. The third semiconductor pattern SP3 may be the shortest among the first to third semiconductor patterns SP1, SP2, and SP3.

A plurality of first source/drain patterns SD1 may be provided on the first active pattern AP1. A plurality of first recesses RS1 may be formed in an upper portion of the first active pattern AP1. The plurality of first source/drain patterns SD1 may be provided in the plurality of first recesses RS1, respectively. The plurality of first source/drain patterns SD1 may be impurity regions of a first conductivity type (e.g., p-type). The first channel pattern CH1 may be interposed between each pair of the plurality of first source/drain patterns SD1. For example, each pair of the plurality of first source/drain patterns SD1 may be connected by the stacked first to third semiconductor patterns SP1, SP2, and SP3.

A plurality of second source/drain patterns SD2 may be provided on the second active pattern AP2. A plurality of second recesses RS2 may be formed in an upper portion of the second active pattern AP2. The plurality of second source/drain patterns SD2 may be provided in the plurality of second recesses RS2, respectively. The plurality of second source/drain patterns SD2 may be impurity regions of a second conductivity type (e.g., n-type). The second channel pattern CH2 may be interposed between each pair of the plurality of second source/drain patterns SD2. For example, each pair of the plurality of second source/drain patterns SD2 may be connected by the stacked first to third semiconductor patterns SP1, SP2, and SP3.

The first and second source/drain patterns SD1 and SD2 may be epitaxial patterns, which may be formed by a selective epitaxial growth (SEG) process. In an embodiment, a top surface of each of the first and second source/drain patterns SD1 and SD2 may be located at substantially the same level as a top surface of the third semiconductor pattern SP3. In another embodiment, the top surface of at least one of the first and second source/drain patterns SD1 and SD2 may be higher than the top surface of the third semiconductor pattern SP3.

The first source/drain patterns SD1 may include a semiconductor material (e.g., SiGe) having a lattice constant greater than that of the substrate 100. In this case, the pair of the first source/drain patterns SD1 may exert a compressive stress on the first channel patterns CH1 therebetween. The second source/drain patterns SD2 may be formed of or include the same semiconductor element (e.g., Si) as the substrate 100.

Referring back to FIG. 5A, the first source/drain pattern SD1 may include a first buffer layer BFL1 and a first main layer MAL1 on the first buffer layer BFL1. The first buffer layer BFL1 may cover or at least partially cover an inner surface of the first recess RS1. In an embodiment, the first buffer layer BFL1 may have a decreasing thickness in an upward direction. For example, a thickness of the first buffer layer BFL1 may be greater when measured in the third direction D3 at a bottom level of the first recess RS1 than when measured in the second direction D2 at an upper level of the first recess RS1. The first buffer layer BFL1 may have a ‘U’-shaped section corresponding to the profile of the first recess RS1.

In an embodiment, a side surface of the first buffer layer BFL1 may have an uneven shape. For example, the side surface of the first buffer layer BFL1 may have a wavy profile. The side surface of the first buffer layer BFL1 may protrude toward first to third inner electrodes PO1, PO2, and PO3 of a gate electrode GE.

The first main layer MAL1 may fill most of the remaining space of the first recess RS1 that includes the first buffer layer BFL1. A volume of the first main layer MAL1 may be greater than a volume of the first buffer layer BFL1. For example, a ratio of the volume of the first main layer MAL1 to a total volume of the first source/drain pattern SD1 may be greater than a ratio of the volume of the first buffer layer BFL1 to the total volume of the first source/drain pattern SD1.

The first buffer layer BFL1 and the first main layer MAL1 may be formed of or include silicon-germanium (SiGe). The first buffer layer BFL1 may contain a relatively low concentration of germanium (Ge). Alternatively, the first buffer layer BFL1 may contain only silicon (Si) without germanium (Ge). The germanium concentration of the first buffer layer BFL1 may range from 0 at % to 10 at %. More specifically, the germanium concentration of the first buffer layer BFL1 may range from 2 at % to 8 at %.

The first main layer MAL1 may contain a relatively high concentration of germanium (Ge). As an example, the germanium concentration of the first main layer MAL1 may range from 30 at % to 70 at %. The germanium concentration of the first main layer MAL1 may increase as a height in the third direction D3 increases. For example, the first main layer MAL1, which is adjacent to the first buffer layer BFL1, may have a germanium concentration of about 40 at %, but an upper portion of the first main layer MAL1 may have a germanium concentration of about 60 at %.

Each of the first buffer layer BFL1 and the first main layer MAL1 may contain at least one impurity (e.g., boron, gallium, or indium) that enables the first source/drain pattern SD1 to have a p-type. The impurity concentration of each of the first buffer layer BFL1 and the first main layer MAL1 may range from 1*10\hat{ }18 atom/cm³ to 5*10\hat{ }22 atom/cm³. The impurity concentration of the first main layer MAL1 may be higher than the impurity concentration of the first buffer layer BFL1.

The first buffer layer BFL1 may prevent a stacking fault from occurring between the substrate 100 (i.e., the first active pattern AP1) and the first main layer MAL1 and between the first to third semiconductor patterns SP1, SP2, and SP3 and the first main layer MAL1. The stacking fault may lead to an increase of a channel resistance. The stacking fault may easily occur on the bottom of the first recess RS1. By contrast, according to an embodiment of the disclosure, the first buffer layer BFL1 may be formed to have a relatively large thickness at a region adjacent to the bottom of the first recess RS1, and in this case, the stacking fault may be prevented.

The first buffer layer BFL1 may protect the first main layer MAL1 in a process of replacing sacrificial layers SAL, which will be described below, with the first to third inner electrodes PO1, PO2, and PO3 of the gate electrode GE. That is, the first buffer layer BFL1 may prevent an etching material, which is used to remove the sacrificial layers SAL, from entering and etching the first main layer MAL1.

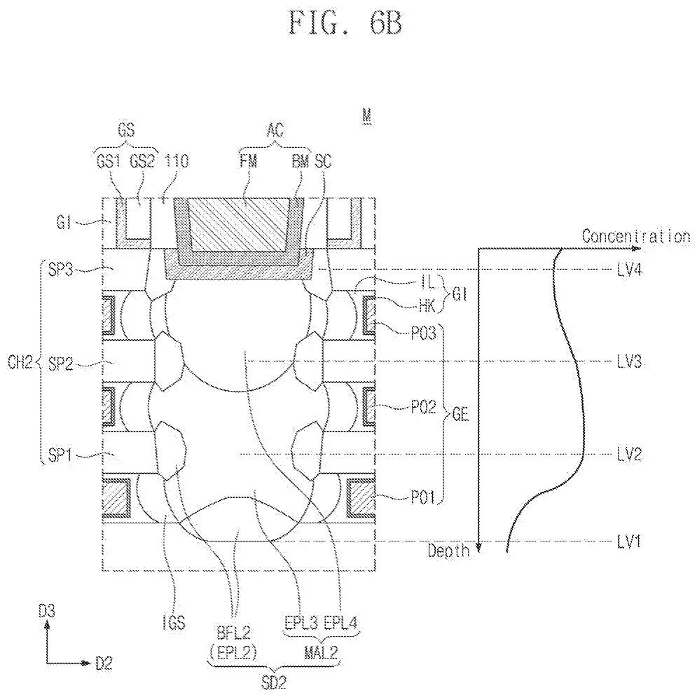

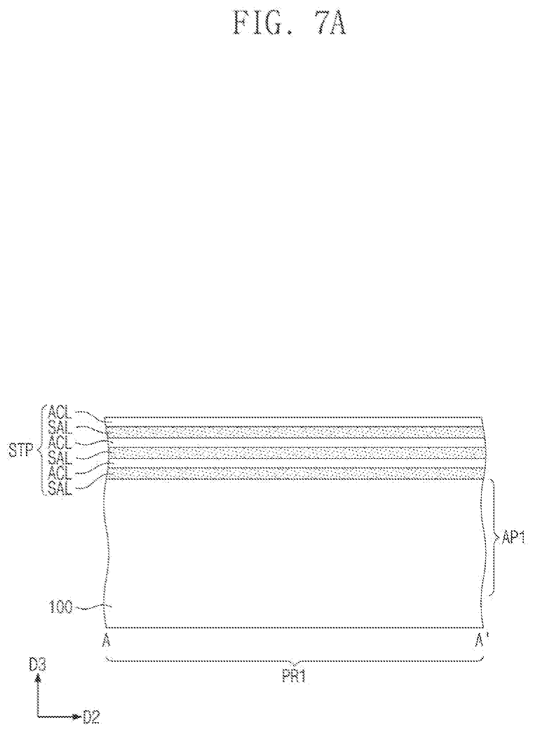

The second source/drain pattern SD2 will be described in more detail with reference to FIGS. 6A and 6B.

Referring back to FIGS. 4 and 5A to 5D, the gate electrodes GE may be provided to cross the first and second channel patterns CH1 and CH2 and to extend in the first direction D1. The gate electrodes GE may be arranged at a first pitch in the second direction D2. Some or all of the gate electrodes GE may be vertically overlap the first and second channel patterns CH1 and CH2.

The gate electrode GE may include a first inner electrode PO1 interposed between the active pattern AP1 or AP2 and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring back to FIGS. 5A and 5B, the first to third inner electrodes PO1, PO2, and PO3 of the gate electrode GE may have widths that are different from each other in the second direction D2. In an embodiment, the largest width of the second inner electrode PO2 may be greater than the largest width of the third inner electrode PO3. The largest width of the first inner electrode PO1 may be greater than the largest width of the second inner electrode PO2.

Referring to FIG. 5D, the gate electrode GE may be provided on a top surface TS, a bottom surface BS, and opposite side surfaces SW of each of the first to third semiconductor patterns SP1, SP2, and SP3. That is, the transistor according to the present embodiment may be a three-dimensional FET (e.g., multi-bridge channel FET (MBCFET™) or gate-all-around FET (GAAFET)) in which the gate electrode GE is provided to three-dimensionally surround the channel pattern.

Referring back to FIG. 4 and FIGS. 5A to 5D, the first single height cell SHC1 may have a first border BD1 and a second border BD2, which are opposite to each other in the second direction D2. The first and second borders BD1 and BD2 may extend in the first direction D1. The first single height cell SHC1 may have a third border BD3 and a fourth border BD4, which are opposite to each other in the first direction D1. The third and fourth borders BD3 and BD4 may extend in the second direction D2.

Gate cutting patterns CT may be disposed on a border, which is parallel to the second direction D2, of each of the first and second single height cells SHC1 and SHC2. For example, the gate cutting patterns CT may be disposed on the third and fourth borders BD3 and BD4 of the first single height cell SHC1. The gate cutting patterns CT may be arranged at the first pitch along the third border BD3. The gate cutting patterns CT may be arranged at the first pitch along the fourth border BD4. In a plan view, the gate cutting patterns CT on the third and fourth borders BD3 and BD4 may be disposed to overlap the gate electrodes GE, respectively. The gate cutting patterns CT may be formed of or include at least one insulating material (e.g., silicon oxide and silicon nitride).

The gate electrode GE on the first single height cell SHC1 may be separated from the gate electrode GE on the second single height cell SHC2 by the gate cutting pattern CT. The gate cutting pattern CT may be interposed between the gate electrodes GE, which are placed on the first and second single height cells SHC1 and SHC2 aligned to each other in the first direction D1. That is, the gate electrode GE extending in the first direction D1 may be divided into a plurality of the gate electrodes GE by the gate cutting patterns CT.

A pair of gate spacers GS may be respectively disposed on opposite side surfaces of the outer electrode PO4 of the gate electrode GE. The gate spacers GS may extend along the gate electrode GE and in the first direction D1. Top surfaces of the gate spacers GS may be higher than a top surface of the gate electrode GE. The top surfaces of the gate spacers GS may be coplanar with a top surface of a first interlayer insulating layer 110, which will be described below. In an embodiment, the gate spacers GS may be formed of or include at least one of SiCN, SiCON, and SiN. In another embodiment, the gate spacers GS may be a multi-layered structure, which is formed of or includes at least two different materials selected from SiCN, SiCON, and SiN.

A gate capping pattern GP may be provided on the gate electrode GE. The gate capping pattern GP may extend along the gate electrode GE or in the first direction D1. The gate capping pattern GP may be formed of or include a material having an etch selectivity with respect to first and second interlayer insulating layers 110 and 120, which will be described below. The gate capping pattern GP may be formed of or include at least one of SiON, SiCN, SiCON, and SiN.

A gate insulating layer GI may be interposed between the gate electrode GE and the first channel pattern CH1 and between the gate electrode GE and the second channel pattern CH2. The gate insulating layer GI may cover or at least partially cover the top surface TS, the bottom surface BS, and the opposite side surfaces SW of each of the first to third semiconductor patterns SP1, SP2, and SP3. The gate insulating layer GI may cover or at least partially cover a top surface of the device isolation layer ST below the gate electrode GE.

In an embodiment, the gate insulating layer GI may include a silicon oxide layer, a silicon oxynitride layer, and/or a high-k dielectric layer. The high-k dielectric layer may be formed of or include at least one high-k dielectric material with dielectric constants that are higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

In an embodiment, the gate electrode GE may include a first metal pattern and a second metal pattern on the first metal pattern. The first metal pattern may be provided on the gate insulating layer GI and may be adjacent to the first to third semiconductor patterns SP1, SP2, and SP3. The first metal pattern may include a work-function metal, which may be used to adjust a threshold voltage of the transistor. By adjusting a thickness and composition of the first metal pattern, a transistor having a desired threshold voltage may be realized. For example, the first to third inner electrodes PO1, PO2, and PO3 of the gate electrode GE may be composed of the first metal pattern or the work-function metal.

The first metal pattern may include a metal nitride layer. For example, the first metal pattern may include a layer that is composed of at least one metallic material including titanium (Ti), tantalum (Ta), aluminum (Al), tungsten (W) and molybdenum (Mo), and nitrogen (N). In an embodiment, the first metal pattern may further include carbon (C). The first metal pattern may include a plurality of work function metal layers which are stacked.

The second metal pattern may be formed of or include a metallic material with a resistance that is lower than the first metal pattern. For example, the second metal pattern may be formed of or include at least one metallic material including tungsten (W), aluminum (Al), titanium (Ti), and tantalum (Ta). The outer electrode PO4 of the gate electrode GE may include the first metal pattern and the second metal pattern on the first metal pattern.

A first interlayer insulating layer 110 may be provided on the substrate 100. The first interlayer insulating layer 110 may cover or at least partially cover the gate spacers GS and the first and second source/drain patterns SD1 and SD2. The first interlayer insulating layer 110 may have a top surface that is substantially coplanar with the top surface of the gate capping pattern GP and the top surface of the gate spacer GS. A second interlayer insulating layer 120 may be formed on the first interlayer insulating layer 110 to cover or at least partially cover the gate capping pattern GP. A third interlayer insulating layer 130 may be provided on the second interlayer insulating layer 120. A fourth interlayer insulating layer 140 may be provided on the third interlayer insulating layer 130. In an embodiment, at least one of the first to fourth interlayer insulating layers 110, 120, 130, and 140 may include a silicon oxide layer.

A pair of division structures DB may be provided at both sides of each of the first and second single height cells SHC1 and SHC2 to be opposite to each other in the second direction D2. For example, a pair of the division structures DB may be respectively provided on the first and second borders BD1 and BD2 of the first single height cell SHC1. The division structure DB may extend in the first direction D1 to be parallel to the gate electrodes GE. A pitch between the division structure DB and the gate electrode GE adjacent thereto may be equal to the first pitch.

The division structure DB may be provided to penetrate the gate capping pattern GP and the gate electrode GE and may extend into the first and second active patterns AP1 and AP2. The division structure DB may be provided to penetrate an upper portion of each of the first and second active patterns AP1 and AP2. The division structure DB may electrically separate an active region of each of the first and second single height cells SHC1 and SHC2 from an active region of a neighboring cell.

Active contacts AC may be provided to penetrate the first and second interlayer insulating layers 110 and 120 and to be electrically connected to the first and second source/drain patterns SD1 and SD2, respectively. A pair of the active contacts AC may be respectively provided at both sides of the gate electrode GE. In a plan view, the active contact AC may be a bar-shaped pattern that extends in the first direction D1.

The active contact AC may be a self-aligned contact. For example, the active contact AC may be formed by a self-alignment process using the gate capping pattern GP and the gate spacer GS. For example, the active contact AC may cover at least a portion of the side surface of the gate spacer GS. The active contact AC may cover a portion of the top surface of the gate capping pattern GP.

Metal-semiconductor compound layers SC (e.g., silicide layers) may be respectively interposed between the active contact AC and the first source/drain pattern SD1 and between the active contact AC and the second source/drain pattern SD2. The active contact AC may be electrically connected to the source/drain pattern SD1 or SD2 through the metal-semiconductor compound layer SC. For example, the metal-semiconductor compound layer SC may be formed of or include at least one of titanium silicide, tantalum silicide, tungsten silicide, nickel silicide, and cobalt silicide.

Referring to FIG. 5C, at least one of the active contacts AC on the first single height cell SHC1 may electrically connect the first source/drain pattern SD1 of the first PMOSFET region PR1 to the second source/drain pattern SD2 of the first NMOSFET region NR1. The active contact AC may extend from the second source/drain pattern SD2 of the first NMOSFET region NR1 to the first source/drain pattern SD1 of the first PMOSFET region PR1 in the first direction D1.

The active contact AC may include a barrier metal BM and a filler metal FM on the barrier metal BM. The barrier metal BM may be provided to enclose all surfaces of the filler metal FM, except for the top surface of the filler metal FM. For example, the filler metal FM may be formed of or include at least one of molybdenum, tungsten, ruthenium, cobalt, and vanadium. In an embodiment, the filler metal FM may be formed of or include molybdenum. The barrier metal BM may include a metal nitride layer. The metal nitride layer may be formed of or include at least one of titanium nitride (TiN), tantalum nitride (TaN), tungsten nitride (WN), nickel nitride (NiN), cobalt nitride (CON), and platinum nitride (PtN).

Gate contacts GC may be provided to penetrate the third interlayer insulating layer 130, the second interlayer insulating layer 120, and the gate capping pattern GP and to be electrically connected to the gate electrodes GE, respectively. In a plan view, two gate contacts GC on the first single height cell SHC1 may be disposed over the first PMOSFET region PR1. That is, the two gate contacts GC on the first single height cell SHC1 may be provided on the first active pattern AP1 (e.g., see FIG. 5A). In a plan view, one gate contact GC on the first single height cell SHC1 may be disposed over the first NMOSFET region NR1. For example, the one gate contact GC on the first single height cell SHC1 may be provided on the second active pattern AP2 (e.g., see FIG. 5B).

The gate contact GC may be freely disposed on the gate electrode GE, without any restrictions on its position. For example, the gate contacts GC on the second single height cell SHC2 may be respectively disposed on the second PMOSFET region PR2, the second NMOSFET region NR2, and the device isolation layer ST filling or at least partially filling the trench TR (e.g., see FIG. 4).

In an embodiment, referring to FIGS. 5A and 5B, an upper portion of the active contact AC adjacent to the gate contact GC may be filled or at least partially filled with an upper insulating pattern UIP. A bottom surface of the upper insulating pattern UIP may be lower than a bottom surface of the gate contact GC. For example, a top surface of the active contact AC adjacent to the gate contact GC may be formed at a level which is lower than the bottom surface of the gate contact GC. Accordingly, the gate contact GC and the active contact AC, which are adjacent to each other, may be prevented from contacting each other and thereby preventing a short circuit issue from occurring therebetween.

A first via VI1 may be provided on the active contact AC. A top surface of the first via VI1 may be located at the same level as a top surface of the gate contact GC (e.g., see FIG. 5B). In an embodiment, the first via VI1 and the gate contact GC may be formed at the same time (for example, using the same process). The first via VI1 and the gate contact GC may be formed of or include the same material. The first via VI1 and the gate contact GC may be formed of or include at least one of molybdenum, tungsten, ruthenium, cobalt, and vanadium.

A first metal layer M1 may be provided in the third interlayer insulating layer 130. For example, the first metal layer M1 may include the first power line M1_R1, the second power line M1_R2, the third power line M1_R3, and first interconnection lines M1_I. The interconnection lines M1_R1, M1_R2, M1_R3, and M1_I of the first metal layer M1 may extend in the second direction D2 to be parallel to each other.

The first and second power lines M1_R1 and M1_R2 may be provided on the third and fourth borders BD3 and BD4 of the first single height cell SHC1, respectively. The first power line M1_R1 may extend along the third border BD3 and in the second direction D2. The second power line M1_R2 may extend along the fourth border BD4 and in the second direction D2.

The first interconnection lines M1_I of the first metal layer M1 may be arranged at a second pitch in the first direction D1. In an embodiment, the second pitch may be less than the first pitch. A linewidth of each of the first interconnection lines M1_I may be less than a linewidth of each of the first to third power lines M1_R1, M1_R2, and M1_R3.

The active contact AC and the interconnection line of the first metal layer M1 may be electrically connected through the first via VI1. The gate electrode GE and the interconnection line of the first metal layer M1 may be electrically connected through the gate contact GC.

The interconnection line of the first metal layer M1 and the first via VI1 thereunder may be formed by separate processes. For example, the interconnection line and the first via VI1 of the first metal layer M1 may be independently formed by respective single damascene processes. The semiconductor device according to the present embodiment may be fabricated using a sub-20 nm process.

A second metal layer M2 may be provided in the fourth interlayer insulating layer 140. The second metal layer M2 may include a plurality of second interconnection lines M2_I. Each of the second interconnection lines M2_I of the second metal layer M2 may be a line-shaped or bar-shaped pattern that extends in the first direction D1. For example, the second interconnection lines M2_I may extend in the first direction D1 and may be parallel to each other.

The second metal layer M2 may further include second vias VI2, which are respectively provided below the second interconnection lines M2_I. The interconnection lines of the first and second metal layers M1 and M2 may be electrically connected through the second via VI2. The interconnection line of the second metal layer M2 and the second via VI2 thereunder may be formed together by a dual damascene process.

The interconnection lines of the first metal layer M1 may be formed of or include a conductive material that is the same as or different from those of the second metal layer M2. For example, the interconnection lines of the first and second metal layers M1 and M2 may be formed of or include at least one metallic material (e.g., copper, ruthenium, aluminum, tungsten, molybdenum, and cobalt). A plurality of metal layers (e.g., M3, M4, M5, and so forth) may be additionally stacked on the fourth interlayer insulating layer 140. Each of the stacked metal layers may include interconnection lines, which are used as routing paths between cells.

FIG. 6A is an enlarged cross-sectional view illustrating a portion ‘M’ of FIG. 5B according to one or more example embodiments of the disclosure. Hereinafter, the second source/drain pattern SD2 will be described in more detail with reference to FIG. 6A. The second source/drain pattern SD2 may include a second buffer layer BFL2 and a second main layer MAL2 on the second buffer layer BFL2. The second buffer layer BFL2 may cover or at least partially cover an inner side surface of the second recess RS2. The second buffer layer BFL2 may have an uneven side surface, similar to the first buffer layer BFL1.

In an embodiment, the second buffer layer BFL2 may include a first epitaxial layer EPL1 and a second epitaxial layer EPL2 on the first epitaxial layer EPL1. The first epitaxial layer EPL1 may directly cover or at least partially cover an inner side surface of the second recess RS2.

The first epitaxial layer EPL1 may be formed of or include a crystalline semiconductor material. For example, the first epitaxial layer EPL1 may be formed of or include undoped silicon (Si), silicon-germanium (SiGe), carbon-doped silicon (Si:C), or carbon-doped silicon-germanium (SiGe:C). In the case where the first epitaxial layer EPL1 includes silicon-germanium (SiGe), the germanium concentration of the first epitaxial layer EPL1 may range from 2 at % to 8 at %. In the case where the first epitaxial layer EPL1 includes carbon-doped silicon (Si:C), the carbon concentration of the first epitaxial layer EPL1 may range from 0.1 at % to 0.5 at %.

The second epitaxial layer EPL2 may be conformally formed on the first epitaxial layer EPL1. In an embodiment, the second epitaxial layer EPL2 may be formed of or include crystalline silicon (Si). The second buffer layer BFL2 may include at least one first impurity (e.g., phosphorus, arsenic, or antimony) that enables the second source/drain pattern SD2 to have an n-type. For example, the first impurity may be arsenic (As).

In an embodiment, the second main layer MAL2 may include a third epitaxial layer EPL3 on the second epitaxial layer EPL2 and a fourth epitaxial layer EPL4 on the third epitaxial layer EPL3. The third epitaxial layer EPL3 may be placed below the fourth epitaxial layer EPLA. In an embodiment, the third epitaxial layer EPL3 may be adjacent to the first semiconductor pattern SP1. The fourth epitaxial layer EPLA may be adjacent to the third semiconductor pattern SP3. An interface between the third epitaxial layer EPL3 and the fourth epitaxial layer EPL4 may be adjacent to the second semiconductor pattern SP2.

Each of the third and fourth epitaxial layers EPL3 and EPL4 may be formed of or include crystalline silicon (Si). As an example, the silicon concentration of each of the third and fourth epitaxial layers EPL3 and EPL4 may range from 85 at % to 100 at %. In an embodiment, the silicon concentration of the fourth epitaxial layer EPL4 may be higher than the silicon concentration of the third epitaxial layer EPL3.

The second main layer MAL2 may include at least one second impurity (e.g., phosphorus, arsenic, or antimony) that enables the second source/drain pattern SD2 to have an n-type. For example, the second impurity may be phosphorus (P).

In an embodiment, the concentration of the second impurity in the third epitaxial layer EPL3 may be higher than the concentration of the second impurity in the fourth epitaxial layer EPL4. The doping profile of the second impurity according to the depth of the second source/drain pattern SD2 will be described in more detail.

The lowermost surface of the second source/drain pattern SD2 may be located at a first level LV1. The first semiconductor pattern SP1 may be located at a second level LV2. The second semiconductor pattern SP2 may be located at a third level LV3. The third semiconductor pattern SP3 may be located at a fourth level LV4. For example, the second level LV2 may correspond to the first semiconductor pattern SP1, the third level LV3 may correspond to the second semiconductor pattern SP2, and the fourth level LV4 may correspond to the third semiconductor pattern SP3.

The concentration of the second impurity in the second source/drain pattern SD2 may gradually increase from the fourth level LV4 toward the third level LV3. The concentration of the second impurity may gradually increase from the third level LV3 to the second level LV2 and may have the highest value at the second level LV2. The concentration of the second impurity may abruptly decrease from the second level LV2 to the first level LV1. The second impurity may have the lowest concentration at the first level LV1.

The concentration of the second impurity in the second source/drain pattern SD2 may be a first atomic fraction CO1 at the second level LV2. The concentration of the second impurity in the second source/drain pattern SD2 may be a second atomic fraction CO2 at the third level LV3. The concentration of the second impurity in the second source/drain pattern SD2 may be a third atomic fraction CO3 at the fourth level LV4. The second atomic fraction CO2 may be higher than the third atomic fraction CO3. The first atomic fraction CO1 may be higher than the second atomic fraction CO2.

In an embodiment, the concentration of the second impurity in the third epitaxial layer EPL3 may be the first atomic fraction CO1 approximately. The concentration of the second impurity in the fourth epitaxial layer EPLA may be the third atomic fraction CO3 approximately. For example, the first atomic fraction CO1 may range from 4 at % to 12 at %. The third atomic fraction CO3 may range from 2 at % to 10 at %. A difference between the first and third atomic fractions CO1 and CO3 may range from 0.5 at % to 2 at %.

In an embodiment, the first to fourth epitaxial layers EPL1 to EPL4 may be respectively formed through separate SEG processes. Since the first to fourth epitaxial layers EPL1 to EPLA include the same material (e.g., Si), an interface between them may not be visible in an image obtained using an electron microscope technique (e.g., scanning electron microscopy (SEM) or transmission electron microscopy (TEM)). However, the first to fourth epitaxial layers EPL1 to EPLA may be doped with different impurities and at different impurity concentrations during the separate SEG processes. That is, the first to fourth epitaxial layers EPL1 to EPL4 may be defined by the difference in the kind or doping profile of impurities therein.

In an embodiment, the gate insulating layer GI may include an interface layer IL and a high-k dielectric layer HK. The high-k dielectric layer HK may be provided to directly enclose the gate electrode GE. The interface layer IL may include a silicon oxide layer, and the high-k dielectric layer HK may include a high-k dielectric material. In an embodiment, a thickness of the interface layer IL between the inner electrode PO1, PO2, or PO3 and the second source/drain pattern SD2 may be greater than a thickness of the interface layer IL between the inner electrode PO1, PO2, or PO3 and the semiconductor pattern SP1, SP2, or SP3.

The gate spacer GS may include a first spacer GS1 and a second spacer GS2. Each of the first and second spacers GS1 and GS2 may be formed of or include a silicon-containing insulating material. The first spacer GS1 may be formed of or include silicon nitride (SiN) or carbon-containing silicon nitride (SiCN). The first spacer GS1 may have a thickness ranging from about 1 nm to about 3 nm. The first spacer GS1 may directly cover or at least partially cover the gate insulating layer GI.

The second spacer GS2 may be formed of or include at least one silicon-containing low-k dielectric material (e.g., SiCON). The second spacer GS2 may be thicker than the first spacer GS1. The second spacer GS2 may have a thickness ranging from about 5 nm to about 12 nm. A dielectric constant of the second spacer GS2 may be lower than a dielectric constant of the first spacer GS1.

In a comparative example, a main layer may be composed of only a third epitaxial layer, without a fourth epitaxial layer. In this case, the second impurities (e.g., phosphorus) may be diffused to an upper portion of the second source/drain pattern, and thus, the concentration of the second impurity may have a gradually increasing doping profile from the second level toward the fourth level. That is, the concentration of the second impurity may have the highest value at the fourth level. Since the third semiconductor pattern has the shortest length and the second impurity concentration has the highest value at the fourth level, a current may be concentrated on the third semiconductor pattern during an operation of the transistor.

By contrast, according to an embodiment of the disclosure, the fourth epitaxial layer EPL4, which has a relatively low concentration of the second impurity, may be added in an upper portion of the second source/drain pattern SD2 to lower the concentration of the second impurity at the fourth level LV4. In particular, the concentration of the second impurity may have the highest value at the position of the first semiconductor pattern SP1 (i.e., the second level LV2). Accordingly, the current may be uniformly distributed to the first to third semiconductor patterns SP1-SP3 during the operation of the transistor. That is, the effective channel length may be controlled to prevent the device from being deteriorated by the short channel effect, and thereby to improve the electric characteristics of the device.

FIG. 6B is an enlarged cross-sectional view illustrating the portion ‘M’ of FIG. 5B according to one or more example embodiments of the disclosure. FIG. 6B includes aspects similar to those of FIG. 6A, and repeated descriptions may be omitted.

Referring to FIG. 6B, an inner spacer IGS may be interposed between each of the first to third inner electrodes PO1, PO2, and PO3 and the second source/drain pattern SD2. The gate insulating layer GI may be spaced apart from the second source/drain pattern SD2 by the inner spacer IGS. The inner spacer IGS may be formed of or include at least one silicon-containing insulating material. For example, the inner spacer IGS may be formed of or include at least one of silicon oxide, silicon nitride, and silicon oxynitride.

The first epitaxial layer EPL1 may be omitted from the second buffer layer BFL2. The second epitaxial layer EPL2 previously described with reference to FIG. 6A may be provided on the side surface of the semiconductor pattern SP1, SP2, or SP3 and the bottom surface of the second recess RS2. The second epitaxial layer EPL2 may not be provided on the inner spacer IGS.

The second main layer MAL2 may include the third epitaxial layer EPL3 and the fourth epitaxial layer EPLA on the third epitaxial layer EPL3. As described with reference to FIG. 6A, the fourth epitaxial layer EPL4 may be placed in an upper portion of the second source/drain pattern SD2, and the third epitaxial layer EPL3 may be placed in a lower portion of the second source/drain pattern SD2. The concentration of the second impurity (e.g., phosphorus) in the third epitaxial layer EPL3 may be higher than the concentration of the second impurity in the fourth epitaxial layer EPL4.

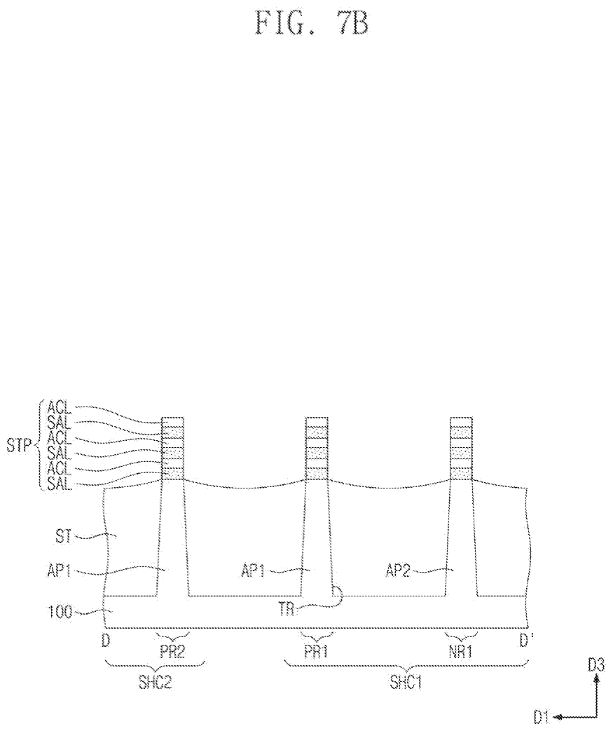

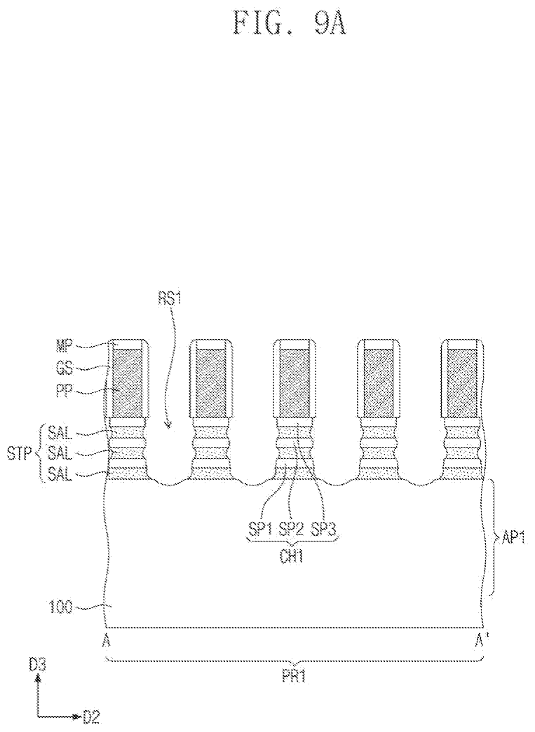

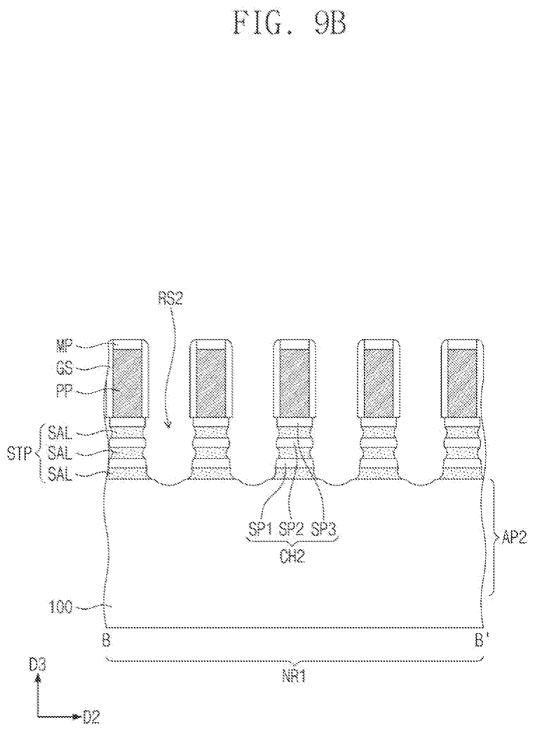

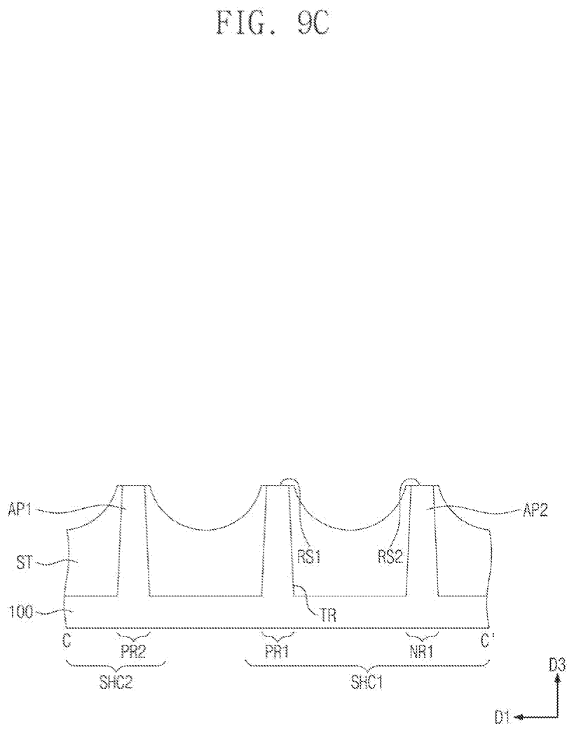

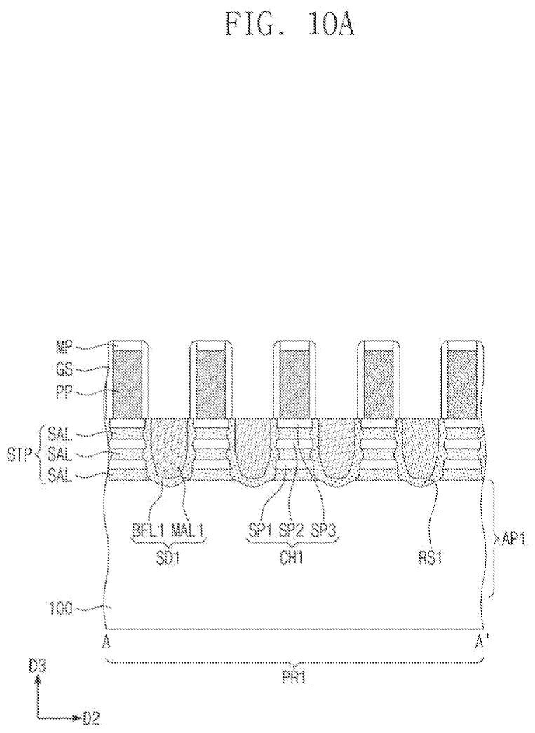

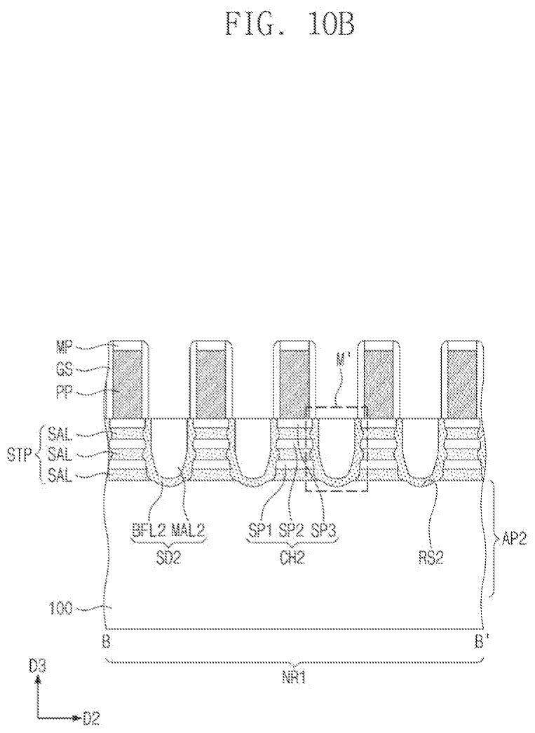

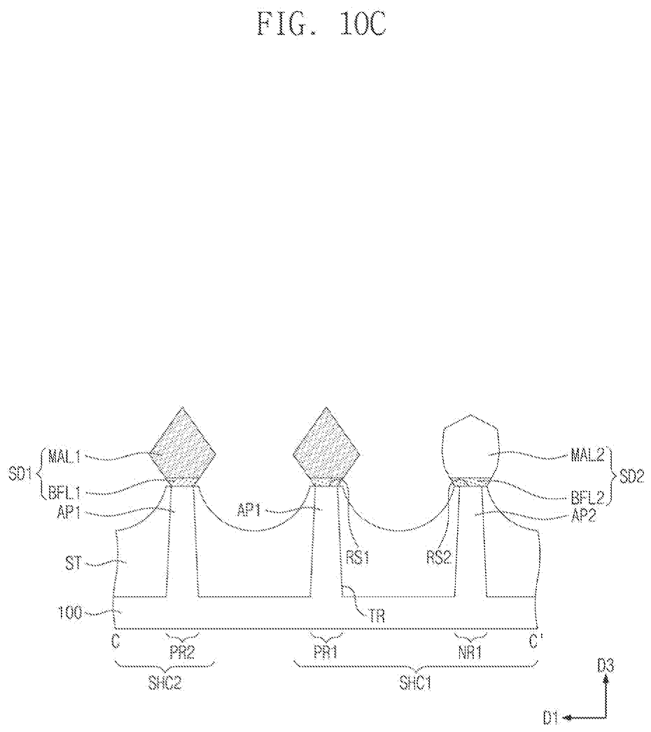

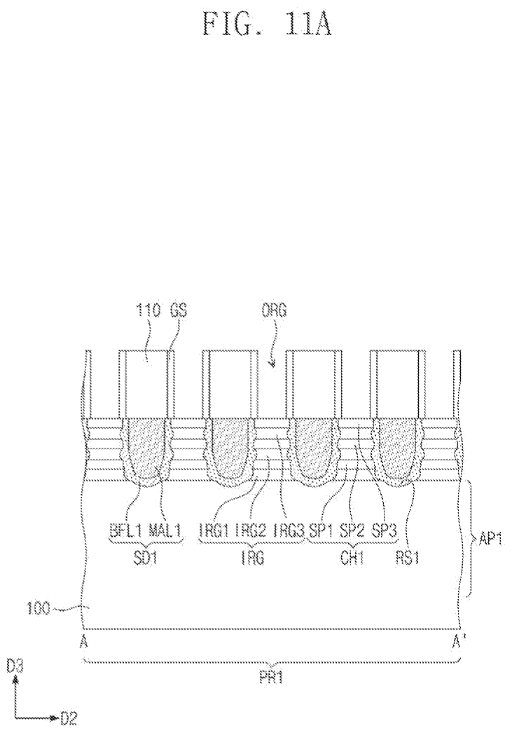

FIGS. 7A to 12C are cross-sectional views illustrating a method of fabricating a semiconductor device, according to one or more example embodiments of the disclosure. FIGS. 7A, 8A, 9A, 10A, 11A, and 12A are cross-sectional views corresponding to the line A-A′ of FIG. 4. FIGS. 9B, 10B, 11B, and 12B are cross-sectional views corresponding to the line B-B′ of FIG. 4. FIGS. 9C and 10C are cross-sectional views corresponding to the line C-C′of FIG. 4. FIGS. 7B, 8B, 11C, and 12C are cross-sectional views corresponding to the line D-D′ of FIG. 4.

Referring to FIGS. 7A and 7B, the substrate 100 including the first and second PMOSFET regions PR1 and PR2 and the first and second NMOSFET regions NR1 and NR2 may be provided. Active and sacrificial layers ACL and SAL may be alternately stacked on the substrate 100. The active and sacrificial layers ACL and SAL may be formed of or include at least one of silicon (Si), germanium (Ge), and silicon-germanium (SiGe), and the active and sacrificial layers ACL and SAL may be formed of different materials from each other.

The sacrificial layer SAL may be formed of at least one material having an etch selectivity with respect to the active layer ACL. For example, the active layers ACL may be formed of or include silicon (Si), and the sacrificial layers SAL may be formed of or include silicon germanium (SiGe). A germanium concentration of each of the sacrificial layers SAL may range from 10 at % to 30 at %.

Mask patterns may be respectively formed on the first and second PMOSFET regions PR1 and PR2 and the first and second NMOSFET regions NR1 and NR2 of the substrate 100. The mask pattern may be a line-shaped or bar-shaped pattern that extends in the second direction D2.

A patterning process using the mask patterns as an etch mask may be performed to form the trench TR defining the first and second active patterns AP1 and AP2. The first active pattern AP1 may be formed on each of the first and second PMOSFET regions PR1 and PR2. The second active pattern AP2 may be formed on each of the first and second NMOSFET regions NR1 and NR2.

A stacking pattern STP may be formed on each of the first and second active patterns AP1 and AP2. The stacking pattern STP may include the active layers ACL and the sacrificial layers SAL which are alternately stacked on top of each other. The stacking pattern STP may be formed together with the first and second active patterns AP1 and AP2, during the patterning process.

The device isolation layer ST may be formed to fill or at least partially fill the trench TR. An insulating layer may be formed on the substrate 100 to cover or at least partially cover the first and second active patterns AP1 and AP2 and the stacking patterns STP. The device isolation layer ST may be formed by recessing the insulating layer to expose the stacking patterns STP.

The device isolation layer ST may be formed of or include at least one insulating material (e.g., silicon oxide). The stacking patterns STP may be placed above the device isolation layer ST and may be exposed to the outside of the device isolation layer ST. For example, the stacking patterns STP may protrude vertically above the device isolation layer ST.

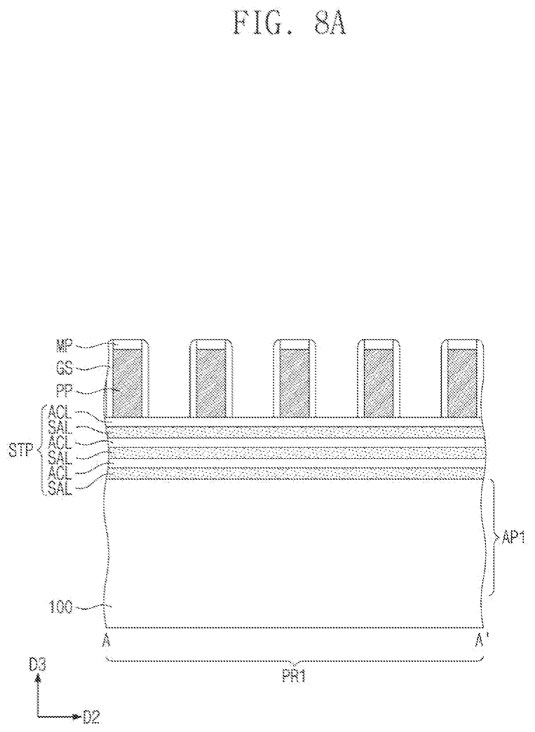

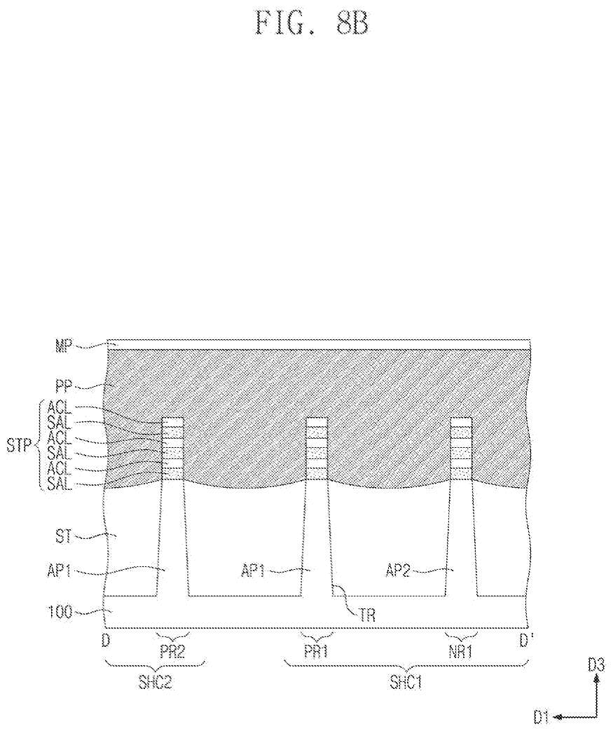

Referring to FIGS. 8A and 8B, sacrificial patterns PP may be formed on the substrate 100 to cross the stacking patterns STP. Each of the sacrificial patterns PP may be a line-shaped or bar-shaped pattern that extends in the first direction D1. The sacrificial patterns PP may be arranged at a first pitch in the second direction D2.

The formation of the sacrificial patterns PP may include forming a sacrificial layer on the substrate 100, forming hard mask patterns MP on the sacrificial layer, and patterning the sacrificial layer using the hard mask patterns MP as an etch mask. In an embodiment, the sacrificial layer may be formed of or include polysilicon.

A pair of the gate spacers GS may be formed on opposite side surfaces of each of the sacrificial patterns PP. The formation of the gate spacers GS may include conformally forming a gate spacer layer on the substrate 100 and anisotropically etching the gate spacer layer. In an embodiment, the gate spacer GS may be a multi-layered structure including at least two layers (e.g., GS1 and GS2 of FIG. 6A).

Referring to FIGS. 9A to 9C, the first recesses RS1 may be formed in the stacking pattern STP on the first active pattern AP1. The second recesses RS2 may be formed in the stacking pattern STP on the second active pattern AP2. During the formation of the first and second recesses RS1 and RS2, the device isolation layer ST may be further recessed at both sides of each of the first and second active patterns AP1 and AP2 (e.g., see FIG. 9C).

The first recesses RS1 may be formed by etching the stacking pattern STP on the first active pattern AP1 using the gate spacer GS as an etch mask. The first recess RS1 may be formed between a pair of the sacrificial patterns PP. The second recesses RS2 may be formed by etching the stacking pattern STP on the second active pattern AP2 using the gate spacer GS as an etch mask. The second recess RS2 may be formed between a pair of the sacrificial patterns PP.

In an embodiment, the first and second recesses RS1 and RS2 may be sequentially formed through different processes. Alternatively, the first and second recesses RS1 and RS2 may be formed at the same time using the same process.

The sacrificial layers SAL may be exposed through the first and second recesses RS1 and RS2. In an embodiment, a selective etching process may be performed on the exposed sacrificial layers SAL. The etching process may include a wet etching process of removing only silicon-germanium selectively. As a result of the etching process, each of the sacrificial layers SAL may be indented to form an indent region. Due to the presence of the indent region, a side surface of the sacrificial layer SAL may become concave. Due to the presence of the indent region, each of the first and second recesses RS1 and RS2 may have an uneven side surface.

The first to third semiconductor patterns SP1, SP2, and SP3, which are sequentially stacked between adjacent first recesses RS1, may be respectively formed from the active layers ACL. The first to third semiconductor patterns SP1, SP2, and SP3, which are sequentially stacked between adjacent second recesses RS2, may be respectively formed from the active layers ACL. The first to third semiconductor patterns SP1, SP2, and SP3 between adjacent first recesses RS1 may constitute the first channel pattern CH1. The first to third semiconductor patterns SP1, SP2, and SP3 between adjacent second recesses RS2 may constitute the second channel pattern CH2.

Referring to FIGS. 10A to 10C, the first source/drain patterns SD1 may be formed in the first recesses RS1, respectively. The first source/drain pattern SD1 may include the first buffer layer BFL1 and the first main layer MAL1. The second source/drain patterns SD2 may be formed in the second recesses RS2, respectively. The second source/drain pattern SD2 may include the second buffer layer BFL2 and the second main layer MAL2.

The first buffer layer BFL1 may be formed by a first SEG process using an inner surface of the first recess RS1 as a seed layer. The first buffer layer BFL1 may be grown using the first to third semiconductor patterns SP1, SP2, and SP3 and the sacrificial layers SAL as a seed layer. In an embodiment, the first SEG process may include a chemical vapor deposition (CVD) process or a molecular beam epitaxy (MBE) process.

The first buffer layer BFL1 may be formed of or include a semiconductor material (e.g., SiGe) with a lattice constant that is greater than that of the substrate 100. The first buffer layer BFL1 may contain a relatively low concentration of germanium (Ge). Alternatively, the first buffer layer BFL1 may contain only silicon (Si) without germanium (Ge). The germanium concentration of the first buffer layer BFL1 may range from 0 at % to 10 at % and, more specifically, from 2 at % to 8 at %.

The first main layer MAL1 may be formed on the first buffer layer BFL1 to fill or at least partially fill the first recess RS1. The first main layer MAL1 may be formed by performing a second SEG process using an inner side surface of the first buffer layer BFL1 as a seed layer. The first main layer MAL1 may be formed of or include a semiconductor material (e.g., SiGe) with a lattice constant that is greater than that of the substrate 100. The first main layer MAL1 may contain a relatively high concentration of germanium (Ge). As an example, a germanium concentration of the first main layer MAL1 may range from 30 at % to 70 at %. The first main layer MAL1 may be formed to have a germanium concentration gradually increasing in the third direction D3. An impurity (e.g., boron, gallium, or indium) may be injected into the first buffer layer BFL1 and the first main layer MAL1 to enable the first source/drain pattern SD1 to have a p-type conductivity.

The second buffer layer BFL2 may be formed in the second recess RS2. The formation of the second buffer layer BFL2 may be substantially the same or similar as the formation of the first buffer layer BFL1 described above. In an embodiment, the second buffer layer BFL2 may be formed through a third SEG process that is different from the process of forming the first buffer layer BFL1. Alternatively, the first and second buffer layers BFL1 and BFL2 may be formed simultaneously through the first SEG process.

The second main layer MAL2 may be formed on the second buffer layer BFL2. The formation of the second buffer layer BFL2 and the second main layer MAL2 will be described in more detail below.

In an embodiment, the second source/drain pattern SD2 may be formed of or include a semiconductor material (e.g., SiGe) with a lattice constant that is greater than that of a semiconductor material of the substrate 100. During the formation of the second source/drain pattern SD2, the second source/drain pattern SD2 may be doped in-situ with p-type impurities (e.g., boron, gallium, or indium). Alternatively, impurities may be injected into the second source/drain pattern SD2, after the formation of the second source/drain pattern SD2.

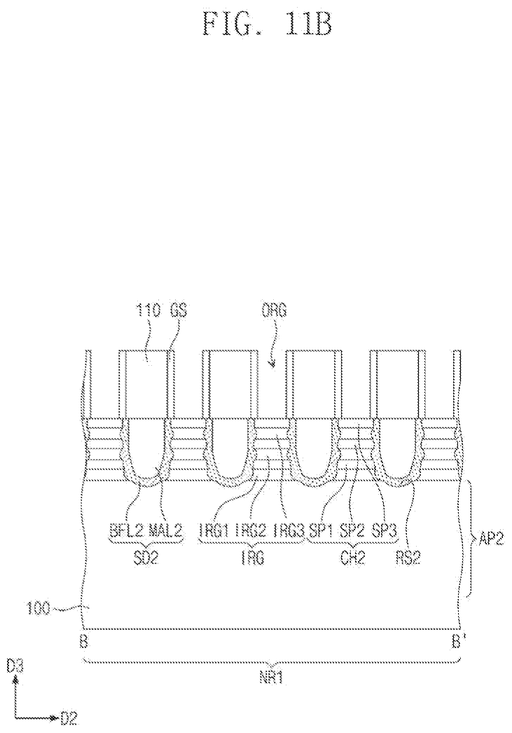

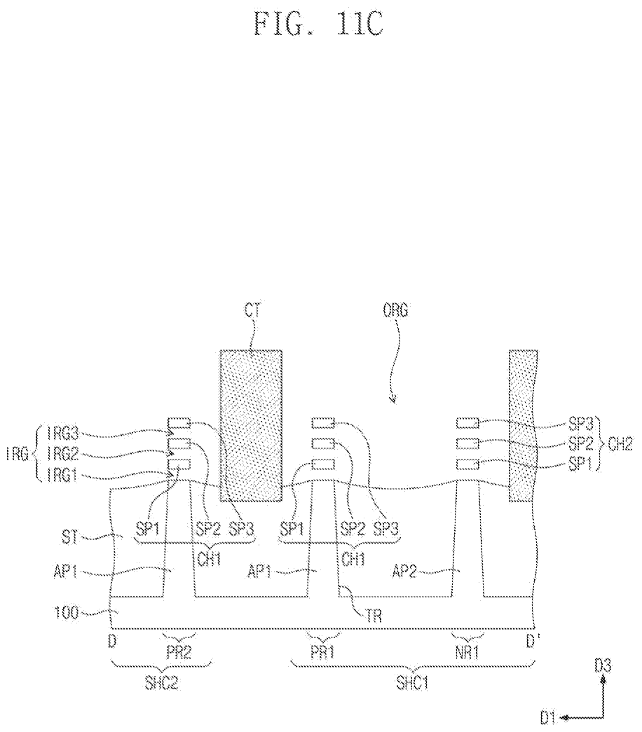

Referring to FIGS. 11A to 11C, the first interlayer insulating layer 110 may be formed to cover or at least partially cover the first and second source/drain patterns SD1 and SD2, the hard mask patterns MP, and the gate spacers GS. In an embodiment, the first interlayer insulating layer 110 may include a silicon oxide layer.

The first interlayer insulating layer 110 may be planarized to expose the top surfaces of the sacrificial patterns PP. The planarization of the first interlayer insulating layer 110 may be performed using an etch-back or chemical-mechanical polishing (CMP) process. All of the hard mask patterns MP may be removed during the planarization process. Accordingly, the first interlayer insulating layer 110 may have a top surface that is coplanar with the top surfaces of the sacrificial patterns PP and the top surfaces of the gate spacers GS.

A photolithography process may be performed to selectively open a region of the sacrificial pattern PP. For example, a region of the sacrificial pattern PP on the third and fourth borders BD3 and BD4 of the first single height cell SHC1 may be selectively opened. The opened region of the sacrificial pattern PP may be selectively etched and removed. The gate cutting pattern CT may be formed by filling or at least partially filling a space, which is formed by removing the sacrificial pattern PP, with an insulating material (e.g., see FIG. 11C).

In an embodiment, the exposed sacrificial patterns PP may be selectively removed. As a result of the removal of the sacrificial patterns PP, an outer region ORG exposing the first and second channel patterns CH1 and CH2 may be formed (e.g., see FIG. 11C). The removal of the sacrificial patterns PP may include a wet etching process which is performed using etching solution capable of selectively etching polysilicon.

The sacrificial layers SAL, which are exposed through the outer region ORG, may be selectively removed to form inner regions IRG (e.g., see FIG. 11C). By performing a process of selectively etching the sacrificial layers SAL, the first to third semiconductor patterns SP1, SP2, and SP3 may be left and only the sacrificial layers SAL may be removed. An etch recipe for the etching process may be chosen to etch a layer (e.g., a silicon germanium layer), which is formed to have a relatively high germanium concentration, at a high etch rate. For example, the etching process may be selected to have a high etch rate to a silicon germanium layer with a germanium concentration that is higher than 10 at %.

The sacrificial layers SAL on the first and second PMOSFET regions PR1 and PR2 and the first and second NMOSFET regions NR1 and NR2 may be removed during the etching process. The etching process may be a wet etching process. An etchant material, which is used in the etching process, may be chosen to quickly remove the sacrificial layer SAL having a relatively high germanium concentration. During the etching process, the first and second source/drain patterns SD1 and SD2 may be protected due to the first and second buffer layers BFL1 and BFL2 having a relatively low concentration of germanium.

Referring back to FIG. 11C, since the sacrificial layers SAL are selectively removed, only the first to third semiconductor patterns SP1, SP2, and SP3, which are stacked on each of the first and second active patterns AP1 and AP2, may be left. Empty regions, which are formed by removing the sacrificial layers SAL, may form first to third inner regions IRG1, IRG2, and IRG3, respectively. The first inner region IRG1 may be formed between the active pattern AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

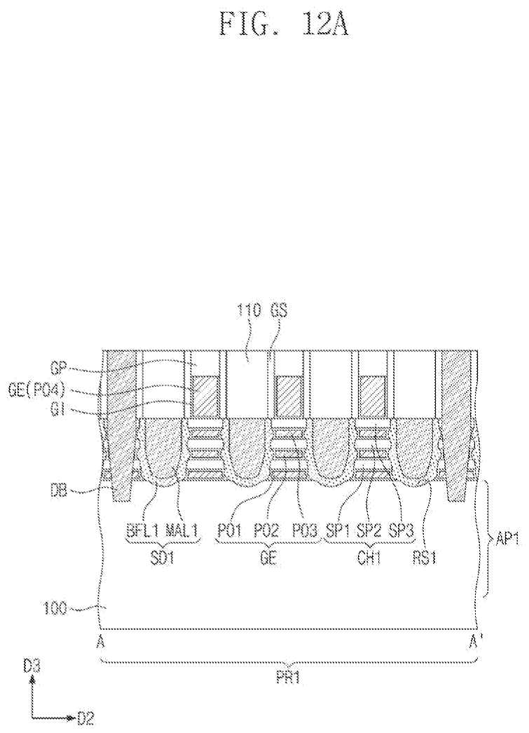

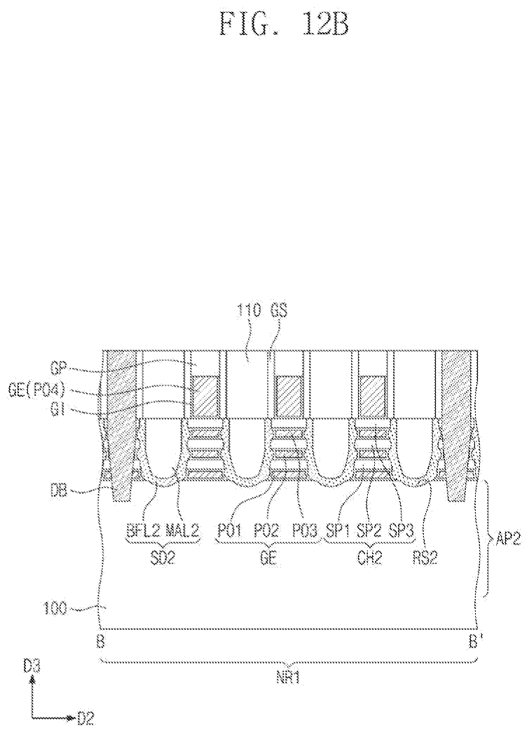

Referring to FIGS. 12A to 12C, the gate insulating layer GI may be formed on the exposed first to third semiconductor patterns SP1, SP2, and SP3. The gate insulating layer GI may be formed to enclose each of the first to third semiconductor patterns SP1, SP2, and SP3. The gate insulating layer GI may be formed in each of the first to third inner regions IRG1, IRG2, and IRG3. The gate insulating layer GI may be formed in the outer region ORG.

The gate electrode GE may be formed on the gate insulating layer GI. The gate electrode GE may include the first to third inner electrodes PO1, PO2, and PO3, which are respectively formed in the first to third inner regions IRG1, IRG2, and IRG3, and the outer electrode PO4, which is formed in the outer region ORG. Each of the first to third inner electrodes PO1, PO2, and PO3 may fill or at least partially fill an inner region (e.g., IRG of FIG. 11C). The gate electrode GE may be recessed to have a reduced height. The gate capping pattern GP may be formed on the recessed gate electrode GE.

Referring back to FIGS. 5A to 5D, the second interlayer insulating layer 120 may be formed on the first interlayer insulating layer 110. The second interlayer insulating layer 120 may include a silicon oxide layer. The active contacts AC may be formed to penetrate the second interlayer insulating layer 120 and the first interlayer insulating layer 110 and to be electrically connected to the first and second source/drain patterns SD1 and SD2.

The formation of the active contact AC may include forming a contact hole in a self-aligned manner using the gate spacer GS, forming the barrier metal BM in the contact hole, and forming the filler metal FM on the barrier metal BM. The barrier metal BM may be conformally formed and may include a metal layer and a metal nitride layer. The filler metal FM may be formed of or include at least one low resistance metal.

The third interlayer insulating layer 130 may be formed on the second interlayer insulating layer 120. The gate contact GC may be formed to penetrate the third interlayer insulating layer 130, the second interlayer insulating layer 120, and the gate capping pattern GP and may be connected to the gate electrode GE. The first via VI1 may be formed to penetrate the third interlayer insulating layer 130 and may be connected to the active contact AC. In an embodiment, the gate contact GC and the first via VI1 may be formed together.

The first metal layer M1 may be formed in the third interlayer insulating layer 130. The interconnection lines M1_R1, M1_R2, M1_R3, and M1_I, which are respectively connected to the gate contact GC and the first via VI1, may be formed in an upper portion of the third interlayer insulating layer 130. The fourth interlayer insulating layer 140 may be formed on the third interlayer insulating layer 130. The second metal layer M2 may be formed in the fourth interlayer insulating layer 140.

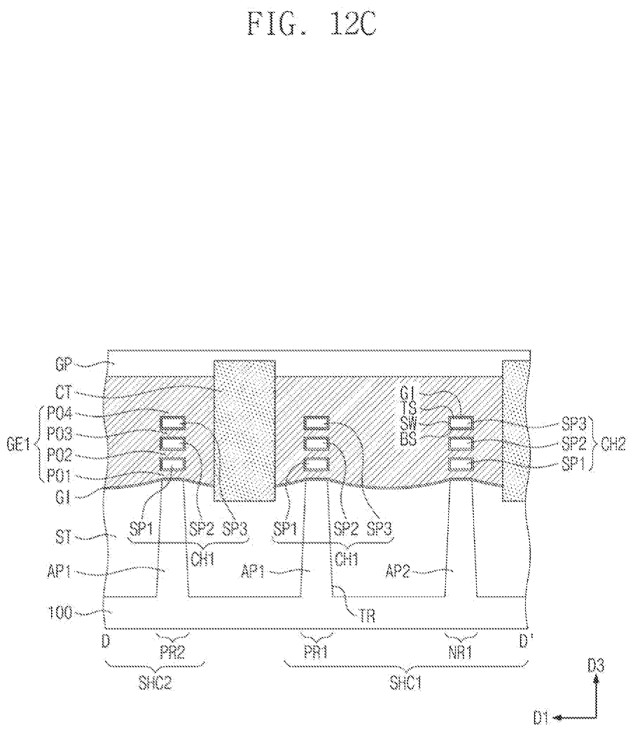

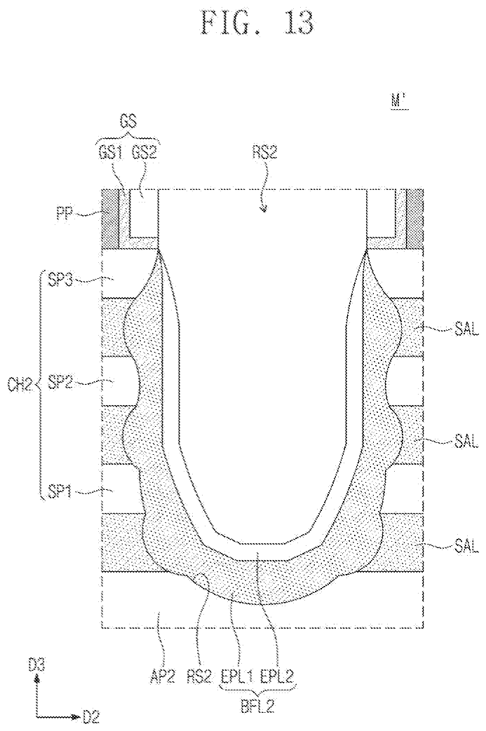

FIGS. 13, 14, and 15 are enlarged cross-sectional views illustrating a portion ‘M” of FIG. 10B and illustrating a method of forming a second source/drain pattern according to one or more example embodiments of the disclosure.

Referring to FIG. 13, the second buffer layer BFL2 may be formed in the second recess RS2. The first epitaxial layer EPL1 may be formed on an inner surface of the second recess RS2 by a first SEG process using the inner surface of the second recess RS2 as a seed layer. The first epitaxial layer EPL1 may be grown using the first to third semiconductor patterns SP1, SP2, and SP3 and the sacrificial layers SAL as the seed layer.

The first epitaxial layer EPL1 may be formed of or include undoped silicon (Si), silicon-germanium (SiGe), carbon-doped silicon (Si:C), or carbon-doped silicon-germanium (SiGe:C). As an example, the first epitaxial layer EPL1 may not be doped with an impurity. Alternatively, the first epitaxial layer EPL1 may be doped with at least one impurity (e.g., phosphorus, arsenic, or antimony).

The second epitaxial layer EPL2 may be formed on the first epitaxial layer EPL1 by a second SEG process using the first epitaxial layer EPL1 as a seed layer. The second epitaxial layer EPL2 may be formed of or include silicon (Si). The second epitaxial layer EPL2 may be doped with at least one n-type first impurity (e.g., phosphorus, arsenic, or antimony). For example, the first impurity may be arsenic (As).

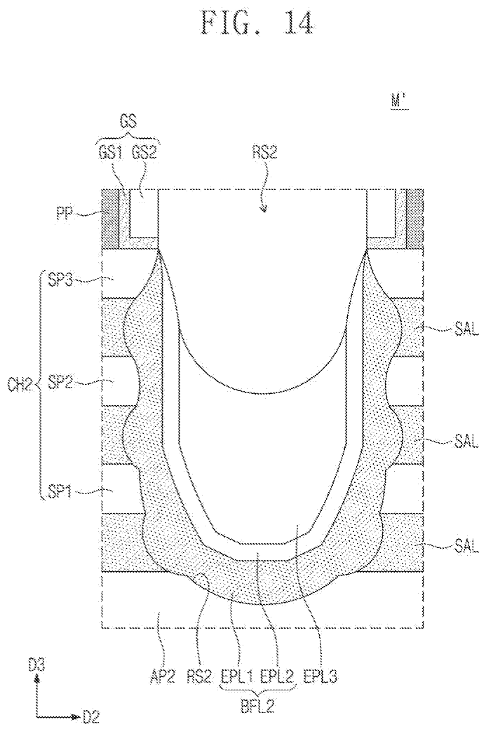

Referring to FIG. 14, the third epitaxial layer EPL3 may be formed on the second epitaxial layer EPL2 by a third SEG process using the second epitaxial layer EPL2 as a seed layer. The third epitaxial layer EPL3 may be formed to partially fill the second recess RS2. The third epitaxial layer EPL3 may be formed so as not to fill an upper portion of the second recess RS2.

The third epitaxial layer EPL3 may be formed of or include silicon (Si). The third epitaxial layer EPL3 may be doped with at least one n-type second impurity (e.g., phosphorus, arsenic, and antimony). For example, the second impurity may be phosphorus (P).

The third epitaxial layer EPL3 may contain the second impurity of a relatively high concentration. For example, the third epitaxial layer EPL3 may be doped to have the second impurity concentration ranging from 4 at % to 12 at %. In an embodiment, the second impurity may be injected into the third epitaxial layer EPL3 in-situ during the third SEG process. Alternatively, the second impurity may be injected into the third epitaxial layer EPL3 through an ion implantation process which is performed after the formation of the third epitaxial layer EPL3.

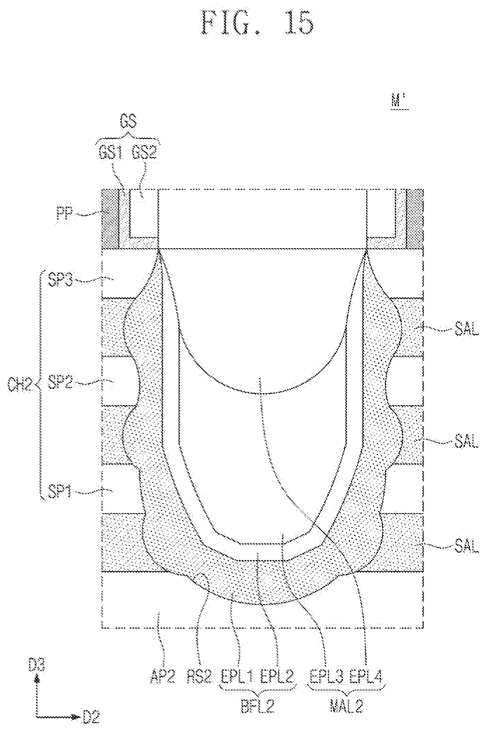

Referring to FIG. 15, the fourth epitaxial layer EPL4 may be formed on the third epitaxial layer EPL3 by a fourth SEG process using the third epitaxial layer EPL3 as a seed layer. The fourth epitaxial layer EPL4 may be formed to fully fill a remaining space of the second recess RS2. The fourth epitaxial layer EPLA may be formed in the upper portion of the second recess RS2.

The fourth epitaxial layer EPL4 may be formed of or include silicon (Si). The fourth epitaxial layer EPL4 may be doped with the n-type second impurity. The fourth epitaxial layer EPLA may be doped to have a high concentration of the second impurity. The concentration of the second impurity in the fourth epitaxial layer EPL4 may be controlled to be lower than the concentration of the second impurity in the third epitaxial layer EPL3.

The fourth epitaxial layer EPL4 may be doped to have the second impurity concentration ranging from 2 at % to 10 at %. In an embodiment, the second impurity may be injected into the fourth epitaxial layer EPL4 in-situ during the fourth SEG process. Alternatively, the second impurity may be injected into the fourth epitaxial layer EPL4 by an ion implantation process that is performed after the formation of the fourth epitaxial layer EPLA.

According to an embodiment of the disclosure, a semiconductor device may include a source/drain pattern, which is formed have an impurity concentration that is decreases as a distance to the uppermost one of stacked nano-sheets decreases. Accordingly, the current may be uniformly provided to the stacked nano-sheets to control an effective channel length in a desired manner, and to prevent the device from being deteriorated by the short channel effect. Therefore, the electric characteristics of the semiconductor device may be improved.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device, comprising:
a substrate comprising an active pattern;
a channel pattern on the active pattern, the channel pattern comprising a first semiconductor pattern, a second semiconductor pattern, and a third semiconductor pattern sequentially stacked and vertically spaced apart;
a source/drain pattern on the active pattern; and
a gate electrode on the first semiconductor pattern, the second semiconductor pattern, and the third semiconductor pattern,
wherein the source/drain pattern comprises a buffer layer and a main layer on the buffer layer,
wherein the main layer comprises silicon that is doped with an impurity,
wherein an impurity concentration of the main layer is a first atomic fraction at a first level corresponding to the first semiconductor pattern,
wherein the impurity concentration of the main layer is a second atomic fraction at a second level corresponding to the second semiconductor pattern,
wherein the impurity concentration of the main layer is a third atomic fraction at a third level corresponding to the third semiconductor pattern, and
wherein the first atomic fraction is greater than the third atomic fraction.

2. The semiconductor device of claim 1, wherein the second atomic fraction is greater than the third atomic fraction, and
wherein the second atomic fraction is less than the first atomic fraction.

3. The semiconductor device of claim 1, wherein the impurity concentration of the main layer decreases from the first level to the third level.

4. The semiconductor device of claim 1, wherein the first atomic fraction is in a range from 4 at % to 12 at %, and
wherein the third atomic fraction is in a range from 2 at % to 10 at %.

5. The semiconductor device of claim 1, wherein a difference between the first atomic fraction and the third atomic fraction is in a range from 0.5 at % to 2 at %.

6. The semiconductor device of claim 1, wherein the impurity is at least one of phosphorus, arsenic, an antimony.

7. The semiconductor device of claim 1, wherein the main layer further comprises a first epitaxial layer and a second epitaxial layer on the first epitaxial layer, and
wherein an impurity concentration of the first epitaxial layer is higher than an impurity concentration of the second epitaxial layer.

8. The semiconductor device of claim 1, wherein the gate electrode comprises an inner electrode between the first semiconductor pattern and the second semiconductor pattern, and
wherein the buffer layer is between the main layer and the inner electrode.

9. The semiconductor device of claim 8, further comprising a gate insulating layer between the inner electrode and the buffer layer,
wherein the gate insulating layer directly contacts the buffer layer.

10. The semiconductor device of claim 1, wherein a length of the first semiconductor pattern is greater than a length of the third semiconductor pattern.

11. A semiconductor device, comprising:
a substrate comprising an active pattern;
a channel pattern on the active pattern, the channel pattern comprising a plurality of semiconductor patterns stacked and vertically spaced apart;
a source/drain pattern on the active pattern; and
a gate electrode on the plurality of semiconductor patterns,
wherein the source/drain pattern comprises an impurity,
wherein the impurity comprises at least one of phosphorus, arsenic, and antimony,
wherein an uppermost semiconductor pattern of the plurality of semiconductor patterns is located at a first level,
wherein a lowermost semiconductor pattern of the plurality of semiconductor patterns is located at a second level, and
wherein an impurity concentration of the source/drain pattern increases from the first level to the second level.

12. The semiconductor device of claim 11, wherein the impurity concentration of the source/drain pattern at the first level is in a range from 4 at % to 12 at %, and
wherein the impurity concentration of the source/drain pattern at the second level is in a range from 2 at % to 10 at %.

13. The semiconductor device of claim 11, wherein a difference between the impurity concentration of the source/drain pattern measured at the first level and the impurity concentration of the source/drain pattern measured at the second level is in a range from 0.5 at % to 2 at %.

14. The semiconductor device of claim 11, wherein a length of the uppermost semiconductor pattern of the plurality of semiconductor patterns is greater than a length of the lowermost semiconductor pattern of the plurality of semiconductor patterns.

15. The semiconductor device of claim 11, wherein the source/drain pattern further comprises a buffer layer and a main layer on the buffer layer, and
wherein the main layer extends from the first level to the second level.

16. A semiconductor device, comprising:
a substrate comprising an n-type metal-oxide-semiconductor (MOS) field effect transistor (FET) (NMOSFET) region;
an active pattern on the NMOSFET region;
a channel pattern on the active pattern, the channel pattern comprising a plurality of semiconductor patterns stacked and spaced apart, the plurality of semiconductor patterns comprising a first semiconductor pattern, a second semiconductor pattern adjacent to the first semiconductor pattern, and an uppermost semiconductor pattern;
a source/drain pattern on the active pattern and comprising an impurity;
a gate electrode on the channel pattern, the gate electrode comprising an inner electrode between the first semiconductor pattern and the second semiconductor pattern, and an outer electrode on the uppermost semiconductor pattern;
a gate insulating layer between the inner electrode and the source/drain pattern;
a gate spacer on a side surface of the outer electrode;
a gate capping pattern on a top surface of the outer electrode;
an interlayer insulating layer on the gate capping pattern and the source/drain pattern;
a gate contact connected to the gate electrode and penetrating the interlayer insulating layer and the gate capping pattern;
an active contact connected to the source/drain pattern and penetrating the interlayer insulating layer; and
a first metal layer on the interlayer insulating layer,
wherein the first metal layer comprises first interconnection lines respectively connected to the gate contact and the active contact,
wherein a length of the first semiconductor pattern is greater than a length of the second semiconductor pattern,
wherein an impurity concentration of the source/drain pattern is a first atomic fraction at a first level corresponding to the first semiconductor pattern,
wherein the impurity concentration of the source/drain pattern is a second atomic fraction at a second level corresponding to the second semiconductor pattern, and
wherein the first atomic fraction is greater than the second atomic fraction.

17. The semiconductor device of claim 16, wherein the gate insulating layer directly contacts the source/drain pattern.

18. The semiconductor device of claim 16, wherein the impurity is at least one of phosphorus, arsenic, and antimony.

19. The semiconductor device of claim 16, wherein a difference between the first atomic fraction and the second atomic fraction is in a range from 0.5 at % to 2 at %.

20. The semiconductor device of claim 16, wherein the first level is lower than the second level.
